(19) United States
(12) Patent Application Publication
(10) Pub. No.: US 2026/0122783 A1
(43) Pub. Date: Apr. 30, 2026

(54) DISPLAY UNIT, ELECTRONIC DEVICE INCLUDING THE SAME, AND METHOD OF MEASURING RESISTANCE OF THE ELECTRONIC DEVICE

(71) Applicant: Samsung Display Co., Ltd., Yongin-si (KR)

(72) Inventors: SEUNGKUK YUN, Yongin-si (KR); WONJONG OHN, Yongin-si (KR); MOON-CHUL PARK, Yongin-si (KR)

(21) Appl. No.: 19/272,901

(22) Filed: Jul. 17, 2025

(30) Foreign Application Priority Data
Oct. 24, 2024 (KR) 10-2024-0146686

(51) Int. Cl. H05K 1/14

(52) U.S. Cl. CPC H05K 1/14; H05K 2201/10128

(57) ABSTRACT

A display unit includes: a display panel including a display area in which pixels are located and a non-display area surrounding at least a portion of the display area; a driving chip attached to the display panel by driving chip bonding portions; a circuit board attached to the display panel by circuit board bonding portions, wherein the circuit board bonding portions include a first circuit board bonding portion electrically separated from the driving chip; and a connector at one side of the circuit board and electrically connected to the first circuit board bonding portion.

### CROSS-REFERENCE TO RELATED APPLICATION

The present application claims priority to and the benefit of Korean Patent Application No. 10-2024-0146686, filed on Oct. 24, 2024, in the Korean Intellectual Property Office, the entire disclosure of which is incorporated herein by reference.

### BACKGROUND

### 1. Field

Aspects of some embodiments of the present disclosure relate to a display unit, an electronic device including the same, and a method of measuring resistance of the electronic device.

### 2. Description of the Related Art

An electronic device may provide a variety of functions, such as displaying images for providing visual information to users. Among electronic devices that provide visual information, an organic light-emitting diode display device has recently attracted attention.

The electronic device may include a display unit. The display unit may include a display panel, a driving chip, and a circuit board. The display panel and the driving chip may be attached to each other by bonding portions, and the display panel and the circuit board may also be attached to each other by bonding portions. Through a test pad and/or the like, resistance of the bonding portion for attaching the display panel and the driving chip and the bonding portion for attaching the display panel and the circuit board may be measured. In this case, a space for arranging the test pad and/or the like is required on the circuit board, and thus area of the circuit board may increase.

The above information disclosed in this Background section is only for enhancement of understanding of the background and therefore the information discussed in this Background section does not necessarily constitute prior art.

### SUMMARY

Aspects of some embodiments of the present disclosure relate to a display unit, an electronic device including the same, and a method of measuring resistance of the electronic device. More particularly, the present disclosure relates to a display unit including a circuit board and a driving chip, an electronic device including the same, and a method of measuring resistance of the electronic device.

Aspects of some embodiments of the present disclosure include a display unit capable of measuring resistance of bonding portions without a test pad.

Aspects of some embodiments of the present disclosure include an electronic device including the display unit.

Aspects of some embodiments of the present disclosure include a method of measuring resistance of the electronic device.

A display unit according to some embodiments includes a display panel including a display area in which pixels are located and a non-display area surrounding at least a portion of the display area, a driving chip attached to the display panel by driving chip bonding portions, a circuit board attached to the display panel by circuit board bonding portions, and a connector located on one side of the circuit board and electrically connected to the first circuit board bonding portion.

In one or more embodiments, the circuit board bonding portions may include a first circuit board bonding portion electrically separated from the driving chip.

In one or more embodiments, the first circuit board bonding portion and the display area may be electrically separated from each other.

In one or more embodiments, the first circuit board bonding portion may be located at an outermost portion of the circuit board bonding portions.

In one or more embodiments, the circuit board bonding portions may further include a second circuit board bonding portion electrically separated from each of the driving chip and the display area, electrically connected to the connector, and adjacent to the first circuit board bonding portion, a third circuit board bonding unit electrically separated from each of the driving chip and the display area, electrically connected to the connector, and adjacent to the second circuit board bonding portion, and a fourth circuit board bonding portion electrically separated from each of the driving chip and the display area, electrically connected to the connector, and adjacent to the third circuit board bonding portion.

In one or more embodiments, the connector may include a terminal including an insertion groove, and the first circuit board bonding portion and the terminal are connected through wiring.

In one or more embodiments, the driving chip bonding portions may include a first driving chip bonding portion electrically separated from the display area and electrically connected to the connector.

In one or more embodiments, the first driving chip bonding portion may be electrically connected to the connector through one of the circuit board bonding portions.

In one or more embodiments, the first driving chip bonding portion may be located at an outermost portion of the driving chip bonding portions.

In one or more embodiments, the display unit may further include an auxiliary circuit board attached to one side of the circuit board through an intermediate connector electrically connected to the connector.

In one or more embodiments, the display unit may further include an auxiliary connector located on one side of the auxiliary circuit board and electrically connected to the first circuit board bonding portion.

In one or more embodiments, the auxiliary connector may be electrically connected to the circuit board bonding portions through the intermediate connector and the connector.

In one or more embodiments, the auxiliary connector may include a terminal including an insertion groove, the intermediate connector may include a terminal electrically connected to the terminal of the auxiliary connector through an auxiliary wiring, and the terminal of the auxiliary connector may be electrically connected to the first circuit board bonding portion through the auxiliary wiring, the terminal of the intermediate connector, the terminal of the connector, and a wiring.

An electronic device according to one or more embodiments includes a display unit and an electronic module configured to control an operation of the display unit.

In one or more embodiments, the display unit may include a display panel including a display area in which pixels are located and a non-display area surrounding at least a portion of the display area, a driving chip attached to the display panel by driving chip bonding portions, a circuit board attached to the display panel by circuit board bonding portions, and a connector located on one side of the circuit board and electrically connected to the first circuit board bonding portion.

In one or more embodiments, the circuit board bonding portions may include a first circuit board bonding portion electrically separated from the driving chip.

A method of measuring resistance of an electronic device according to one or more embodiments includes connecting a first probe to a portion of a connector electrically connected to a first circuit board bonding portion attaching a display panel and a circuit board, connecting a second probe to a portion of the connector electrically connected to a second circuit board bonding portion attaching the display panel and the circuit board, connecting a third probe to a portion of the connector electrically connected to a third circuit board bonding portion attaching the display panel and the circuit board, and connecting a fourth probe to a portion of the connector electrically connected to a fourth circuit board bonding portion attaching the display panel and the circuit board.

In one or more embodiments, the second circuit board bonding portion may be spaced apart from the first circuit board bonding portion in a plan view.

In one or more embodiments, the third circuit board bonding portion may be spaced apart from the first circuit board bonding portion and the second circuit board bonding portion in a plan view.

In one or more embodiments, the fourth circuit board bonding portion may be spaced apart from the first circuit board bonding portion, the second circuit board bonding portion, and the third circuit board bonding portion in a plan view.

In one or more embodiments, the connecting of the first probe to the portion of the connector may include connecting the first probe to a first terminal included in the connector, and the connecting of the second probe to the portion of the connector may include connecting the second probe to a second terminal included in the connector and spaced apart from the first terminal of the connector in a plan view.

In one or more embodiments, the connecting of the third probe to the portion of the connector may include connecting the third probe to a third terminal included in the connector and spaced apart from each of the first terminal of the connector and the second terminal of the connector in a plan view, and the connecting of the fourth probe to the portion of the connector may include connecting the fourth probe to a fourth terminal included in the connector and spaced apart from each of the first terminal of the connector, the second terminal of the connector, and the third terminal of the connector in a plan view.

In one or more embodiments, the method may further include connecting a fifth probe to a portion of the connector electrically connected to a first driving chip bonding portion attaching the display panel and the driving chip, connecting a sixth probe to a portion of the connector electrically connected to a second driving chip bonding portion attaching the display panel and the driving chip and spaced apart from the first driving chip bonding portion, connecting a seventh probe to a portion of the connector electrically connected to a third driving chip bonding portion attaching the display panel and the driving chip and spaced apart from each of the first driving chip bonding portion and the second driving chip bonding portion, and connecting an eighth probe to a portion of the connector electrically connected to a fourth driving chip bonding portion attaching the display panel and the driving chip and spaced apart from each of the first driving chip bonding portion, the second driving chip bonding portion, and the third driving chip bonding portion.

In one or more embodiments, the connecting of the fifth probe to the portion of the connector may include connecting the fifth probe to a fifth terminal included in the connector, and the connecting of the sixth probe to the portion of the connector may include connecting the sixth probe to a sixth terminal included in the connector and spaced apart from the fifth terminal in a plan view.

In one or more embodiments, the connecting of the seventh probe to the portion of the connector may include connecting the seventh probe to a seventh terminal included in the connector and spaced apart from each of the fifth terminal of the connector and the sixth terminal of the connector in a plan view, and the connecting of the eighth probe to the portion of the connector may include connecting the eighth probe to an eighth terminal included in the connector and spaced apart from each of the fifth terminal of the connector, the sixth terminal of the connector, and the seventh terminal of the connector in a plan view.

In one or more embodiments, a current may be configured to be applied to the first circuit board bonding portion through the first probe, a current may be configured to be applied to the second circuit board bonding portion through the second probe, a voltage may be configured to be applied to the third circuit board bonding portion through the third probe, and a voltage may be configured to be applied to the fourth circuit board bonding portion through the fourth probe.

An electronic device according to one or more embodiments includes a display unit and an electronic module configured to control an operation of the display unit. In addition, the display unit may include a display panel including a display area in which pixels are located and a non-display area surrounding at least a portion of the display area, a driving chip attached to the display panel by driving chip bonding portions, a circuit board attached to the display panel by circuit board bonding portions, and a connector located on one side of the circuit board and electrically connected to the first circuit board bonding portion. In addition, the circuit board bonding portions may include a first circuit board bonding portion electrically separated from the driving chip. The first driving chip bonding portion may be electrically connected to the connector.

Accordingly, resistance of the electronic device may be measured through the connector. For example, resistance of some of the circuit board bonding portions of the electronic device may be measured through the connector. In addition, resistance of some of the driving chip bonding portions of the electronic device may be measured through the connector.

Accordingly, even if test pads are omitted in the circuit board, the resistance of some of the circuit board bonding portions and the resistance of some of the driving chip bonding portions may be measured. Accordingly, an area of the circuit board may be relatively reduced, and electrostatic discharge flowing in through the test pads may be prevented or reduced.

In addition, with respect to electronic devices that use a same connector, the probes may not need to be replaced. For example, the probes may be shared among electronic devices that use the same connector.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating an electronic device according to one or more embodiments.

FIG. 2 is a block diagram illustrating the electronic device of FIG. 1.

FIG. 3 is a cross-sectional view illustrating a display module included in the display unit included in the electronic device of FIG. 2.

FIG. 4 is a plan view illustrating an example of some components included in the display unit included in the electronic device of FIG. 2.

FIG. 5 is an enlarged plan view of an area A of FIG. 4.

FIG. 6 is a cross-sectional view of the display unit of FIG. 5 taken along the line I-I′.

FIG. 7 is a cross-sectional view of the display unit of FIG. 5 taken along the line II-II′.

FIG. 8 is a perspective view illustrating a portion of the circuit board of FIG. 5 and a connector.

FIG. 9 is a perspective view illustrating that probes are coupled to the connector of FIG. 8.

FIG. 10 is a perspective view illustrating that a first probe is coupled to a first terminal of the connector of FIG. 9.

FIG. 11 is a cross-sectional view illustrating a pixel included in the display panel of FIG. 4.

FIG. 12 is a plan view illustrating an example of some components included in the display unit included in the electronic device of FIG. 2.

FIG. 13 is an enlarged plan view illustrating an area B of FIG. 12.

FIG. 14 is a plan view illustrating an example of some components included in the display unit included in the electronic device of FIG. 2.

FIG. 15 is an enlarged plan view illustrating an area C of FIG. 14.

FIG. 16 is a perspective view illustrating that an auxiliary circuit board is attached to the circuit board of FIG. 15.

FIG. 17 is a plan view illustrating an auxiliary circuit board, an intermediate connector, and an auxiliary connector of FIG. 15.

### DETAILED DESCRIPTION

Hereinafter, display devices according to some embodiments will be described in more detail with reference to the accompanying drawings. The same reference numerals are used for the same components in the drawings, and redundant descriptions of the same components will be omitted.

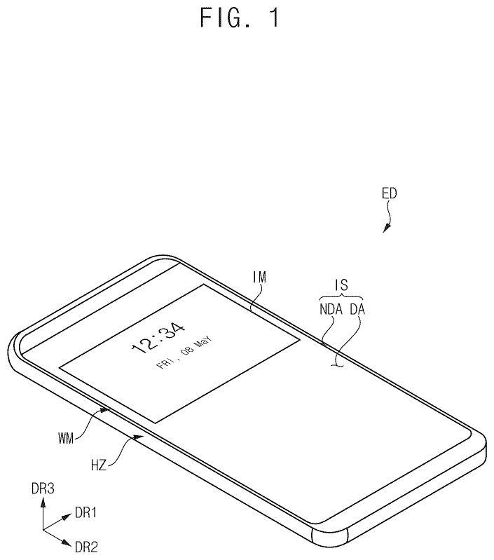

FIG. 1 is a perspective view illustrating an electronic device according to one or more embodiments.

Referring to FIG. 1, an electronic device ED according to one or more embodiments may be a device that is activated by an electrical signal. For example, the electronic device ED may be a small electronic device such as a smartphone, a mobile phone, a smart watch, a game machine, a camera, and/or the like. However, embodiments according to the present disclosure are not necessarily limited thereto, and the electronic device ED may be a medium or large-sized electronic device such as a laptop, a tablet, a PC, a television, a computer monitor, a vehicle monitor, an external billboard, and/or the like.

An upper surface of the electronic device ED may be defined as a display surface IS. The display surface IS may be a surface parallel to a plane formed by a first direction DR1 and a second direction DR2 crossing the first direction DR1. An image IM generated by the electronic device ED may be provided to a user through the display surface IS.

The electronic device ED may include a display area DA and a non-display area NDA. For example, the display surface IS may be divided into the display area DA and the non-display area NDA. The display area DA may be an area in which the image IM is displayed. For example, the display area DA may be an area for displaying the image IM by generating light or adjusting transmittance of light provided from an external light source. The non-display area NDA may surround (e.g., in a periphery or outside a footprint of) at least a portion of the display area DA. For example, the non-display area NDA may entirely surround the display area DA. In one or more embodiments, the non-display area NDA may be an area in which the image IM is not displayed. However, embodiments according to the present disclosure are not necessarily limited thereto, and the image IM may be displayed in a portion of the non-display area NDA. The non-display area NDA may include a plurality of drivers. For example, the non-display area NDA may include a gate driver, a data driver, a light-emitting driver, and/or the like.

The electronic device ED may include a housing HZ and a window WM. The window WM and the housing HZ may be coupled to each other to constitute an external appearance of the electronic device ED. The housing HZ may protect components included in the electronic device ED from external impact. The housing HZ may include a material having relatively high rigidity. For example, the housing HZ may include glass, plastic, metal, and/or the like. These materials may be used alone or in combination with each other. For example, the window WM may be an ultra thin glass or polyimide film, but embodiments according to the present disclosure are not necessarily limited thereto.

In one or more embodiments, the first direction DR1 and the second direction DR2 crossing the first direction DR1 may be defined. For example, the second direction DR2 may be perpendicular to the first direction DR1. However, embodiments according to the present disclosure are not limited thereto, and the second direction DR2 may form an acute angle or an obtuse angle with the first direction DR1. In addition, a third direction DR3 crossing a plane formed by the first direction DR1 and the second direction DR2 may be defined. For example, the third direction DR3 may be perpendicular to the plane formed by the first direction DR1 and the second directions DR2. However, embodiments according to the present disclosure are not limited thereto, and the third direction DR3 may form an acute angle or an obtuse angle with the plane formed by the first direction DR1 and the second direction DR2.

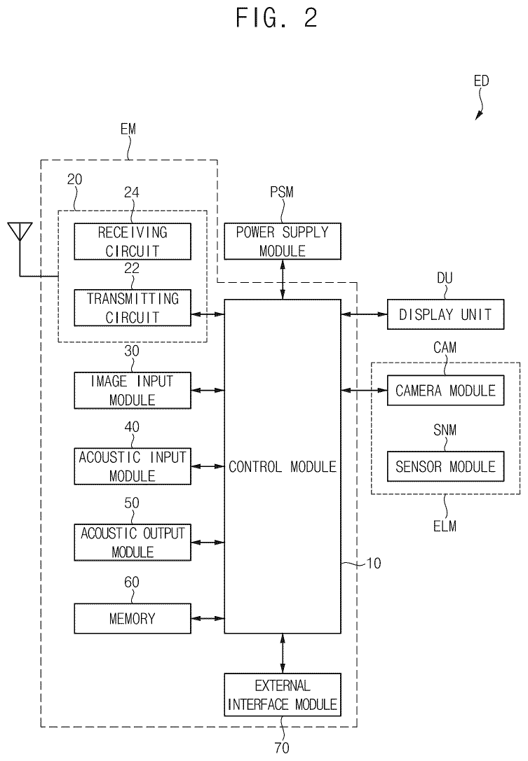

FIG. 2 is a block diagram illustrating the electronic device of FIG. 1.

Referring to FIG. 2, the electronic device ED may include a display unit DU, an electronic module EM, a power supply module PSM, and an electro-optical module ELM. According to some embodiments, the electronic device ED may further include a case receiving the display unit DU, the electronic module EM, and the power supply module PSM.

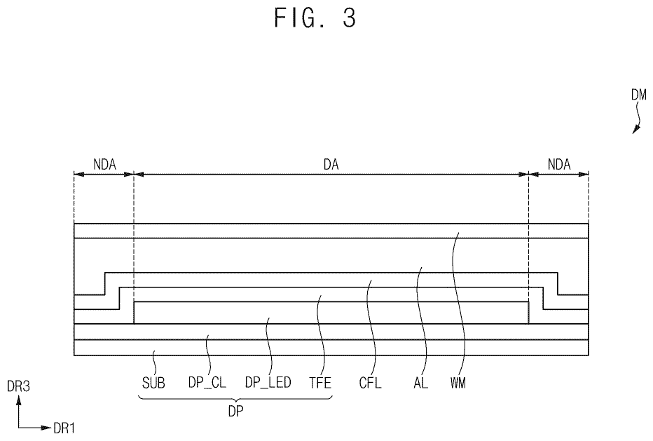

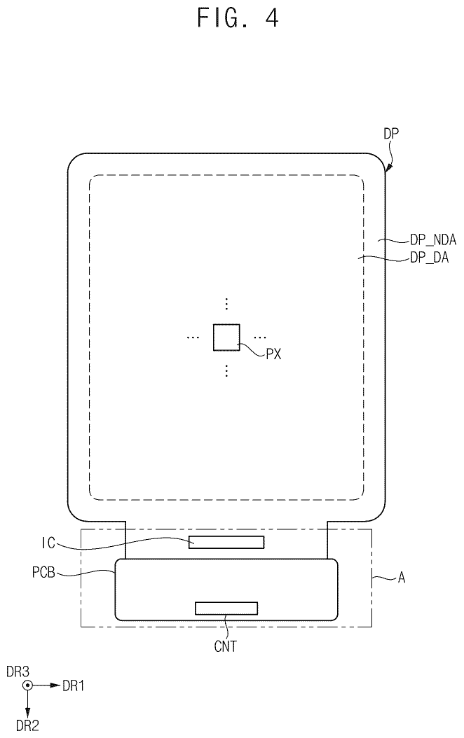

The display unit DU may display an image (e.g., the image IM of FIG. 1). According to some embodiments, the display unit DU may detect an external input such as a user's hand or a stylus pen. The display unit DU may include a display module (e.g., a display module DM of FIG. 3), a driving chip (e.g., a driving chip IC of FIG. 4), a circuit board (e.g., a circuit board PCB of FIG. 4) and a connector (e.g., a connector CNT of FIG. 4).

The electronic module EM may control an operation of the display unit DU. The electronic module EM may be electrically connected to the power supply module PSM. In one or more embodiments, the electronic module EM may include a control module 10, a wireless communication module 20, an image input module 30, an acoustic input module 40, an acoustic output module 50, a memory 60, and an external interface module 70.

The control module 10 may control an overall operation of the electronic device ED. For example, the control module 10 may activate or deactivate the display module according to a user input. In addition, the control module 10 may control the image input module 30, the acoustic input module 40, the acoustic output module 50, and/or the like, according to a user input. The control module 10 may include at least one microprocessor.

The wireless communication module 20 may transmit/receive a wireless signal with another terminal using a Bluetooth or Wi-Fi line. The wireless communication module 20 may transmit/receive a voice signal using a general communication line. In one or more embodiments, the wireless communication module 20 may include a transmitting circuit 22 and a receiving circuit 24. The transmitting circuit 22 may modulate a signal to be transmitted. The receiving circuit 24 may demodulate a received signal.

The image input module 30 may process an image signal and provide image data to the display unit DU. The acoustic input module 40 may receive an external sound signal through a microphone in a recording mode, a voice recognition mode, and/or the like and convert the external sound signal into electrical voice data. The acoustic output module 50 may convert sound data received from the wireless communication module 20 and sound data stored in the memory 60 to output the converted sound data to an outside.

The external interface module 70 may serve as an interface connected to an external charger, a wired/wireless data port, a card socket (e.g., a memory card, a SIM/UIM card, and/or the like), and/or the like.

The power supply module PSM may supply power to the electronic module EM. The power supply module PSM may supply power required for an overall operation of the electronic device ED. For example, the power supply module PSM may include a conventional battery device.

The electro-optical module ELM may be an electronic component that outputs or receives an optical signal. In one or more embodiments, the electro-optical module ELM may include a camera module CAM and a sensor module SNM. The camera module CAM may photograph an external image. The sensor module SNM may include at least one sensor. For example, the sensor module SNM may include an gaze tracking sensor and/or an illuminance sensor. However, embodiments according to the present disclosure are not necessarily limited thereto, and the sensor module SNM may include a sensor different from the gaze tracking sensor and the illuminance sensor. For example, the sensor module SNM may include a proximity sensor, a contact sensor, and/or the like.

In one or more embodiments, the electronic module EM may be electrically connected to a circuit board (e.g., a circuit board PCB of FIG. 4). For example, the electronic module EM may be electrically connected to the circuit board through a connector (e.g., a connector CNT of FIG. 4). For example, the electronic module EM may be mounted on a mother board, and the mother board may be electrically connected to the circuit board through the connector.

FIG. 3 is a cross-sectional view illustrating a display module included in the display unit included in the electronic device of FIG. 2. FIG. 4 is a plan view illustrating an example of some components included in the display unit included in the electronic device of FIG. 2.

Referring to FIGS. 3 and 4, as described above, the display unit (e.g., the display unit DU of FIG. 2) may include a display module DM, a driving chip IC, a circuit board PCB, and a connector CNT. The display module DM may include a display panel DP, a light control layer CFL, an adhesive layer AL, and the window WM. The display panel DP may include a substrate SUB, a circuit layer DP_CL, an element layer DP_LED, and an encapsulation layer TFE.

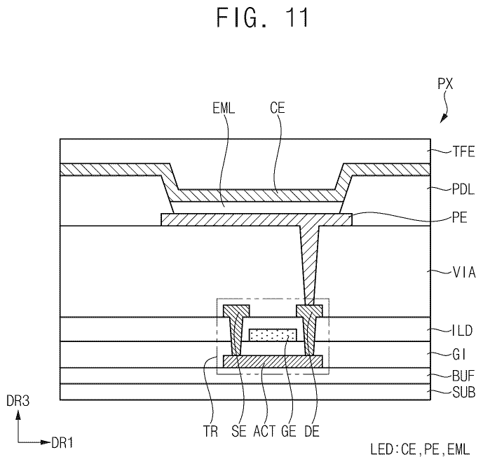

The substrate SUB may be a base of the display panel DP. The circuit layer DP_CL may be located on the substrate SUB. The circuit layer DP_CL may include a circuit element. For example, the circuit layer DP_CL may include a pixel driving circuit portion including transistors and capacitors. For example, the circuit layer DP_CL may include a transistor (e.g., a transistor TR of FIG. 11). The element layer DP_LED may be located on the circuit layer DP_CL. For example, the element layer DP_LED may include a light-emitting element (e.g., the light-emitting element LED of FIG. 11). The encapsulation layer TFE may be located on the element layer DP_LED. The encapsulation layer TFE may seal the element layer DP_LED.

The light control layer CFL may be located on the display panel DP. The light control layer CFL may include a color filter and a black matrix. The color filter may transmit only light having a specific wavelength. The color filter may be arranged to overlap the light-emitting element in a plan view. The black matrix may be located adjacent to the color filter to absorb or block a portion of light emitted from the light-emitting element.

The window WM may be located on the light control layer CFL. The window WM may be attached to the light control layer CFL through the adhesive layer AL. For example, the adhesive layer AL may include an optical clear adhesive (“OCA”), an optical clear resin (“OCR”), or a pressure sensitive adhesive (“PSA”).

As illustrated in FIG. 4, the display panel DP may include a display area DP_DA and a non-display area DP_NDA. The display area DP_DA may correspond to the display area DA of FIG. 1. In addition, the non-display area DP_NDA may correspond to the non-display area NDA of FIG. 1.

The display area DP_DA may display an image (e.g., the image IM of FIG. 1). For example, pixels may be located in the display area DP_DA, and each of the pixels may emit light. For example, a pixel PX may be located in the display area DP_DA, and the pixel PX may emit light. The pixels may be repeatedly arranged along the first direction DR1 and the second direction DR2.

The non-display area DP_NDA may surround at least a portion of the display area DP_DA. For example, the non-display area DP_NDA may entirely surround the display area DP_DA. As described above, the non-display area DP_NDA may include drivers such as a gate driver, a data driver, and a light-emitting driver. The non-display area DP_NDA may include a first portion and a second portion. The first portion of the non-display area DP_NDA may be a portion surrounding the display area DP_DA. The second portion of the non-display area DP_NDA may protrude from the first portion in the second direction DR2. The driving chip IC and the circuit board PCB may be attached to the second portion of the non-display area DP_NDA.

The driving chip IC may be attached to the display panel DP. For example, the driving chip IC may be attached to a portion of the second portion of the non-display area DP_NDA. For example, the driving chip IC may be attached to a center of the second portion of the non-display area DP_NDA, but embodiments according to the present disclosure are not necessarily limited thereto. The driving chip IC may convert a digital data signal among driving signals into an analog data signal. In addition, the driving chip IC may provide the analog data signal to the pixels. In one or more embodiments, as illustrated in FIG. 4, a number of driving chip IC may be one. However, embodiments according to the present disclosure are not necessarily limited thereto, and the number of driving chips IC may be variously changed according to various embodiments.

The circuit board PCB may be attached to the display panel DP. For example, the circuit board PCB may be attached to a portion of the second portion of the non-display area DP_NDA. For example, the circuit board PCB may be attached to one side of the second portion of the non-display area DP_NDA. The circuit board PCB may be spaced apart from the driving chip IC in the second direction DR2. However, embodiments according to the present disclosure are not necessarily limited thereto, and position of the circuit board PCB may be variously changed according to embodiments. The circuit board PCB may apply a driving signal, a driving voltage, and/or the like to the driving chip IC and the pixels. In one or more embodiments, as illustrated in FIG. 4, a number of circuit board PCB may be one. However, embodiments according to the present disclosure are not necessarily limited thereto, and the number of circuit board PCB may be variously changed according to embodiments.

The connector CNT may be located on the circuit board PCB. For example, the connector CNT may be located on an upper surface of the circuit board PCB. The upper surface of the circuit board PCB may be a surface facing in the third direction DR3. The connector CNT may be located on one side of the circuit board PCB. In one or more embodiments, the connector CNT may be located on a lower end of the circuit board PCB in a plan view. As described above, the electronic module (e.g., the electronic module EM of FIG. 2) may be electrically connected to the circuit board PCB through the connector CNT.

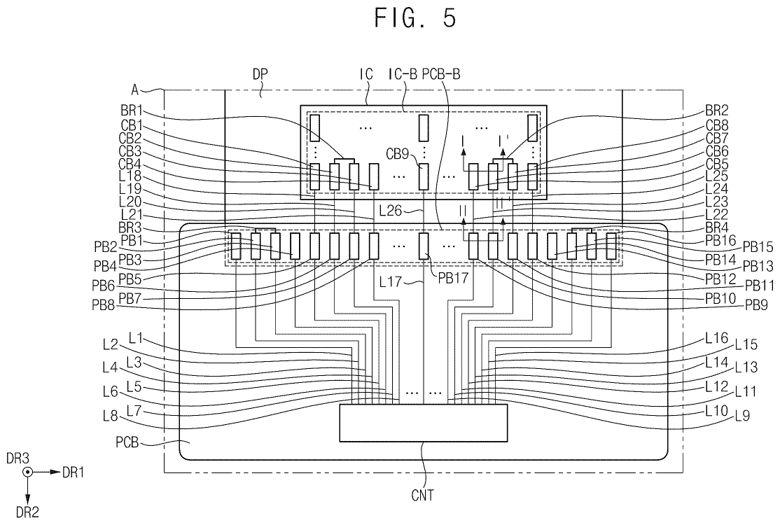

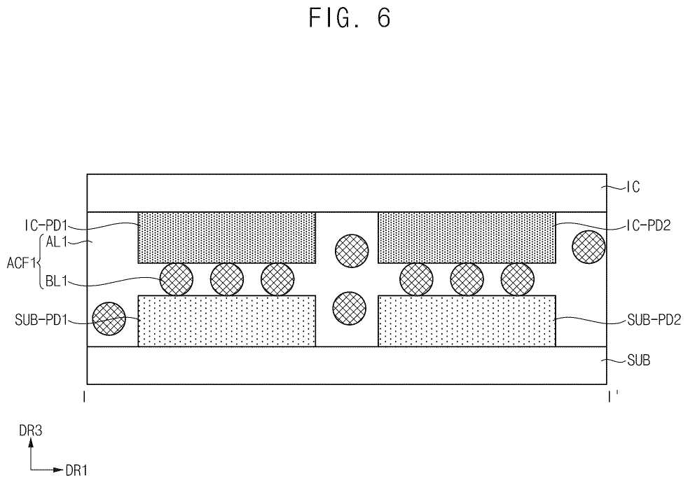

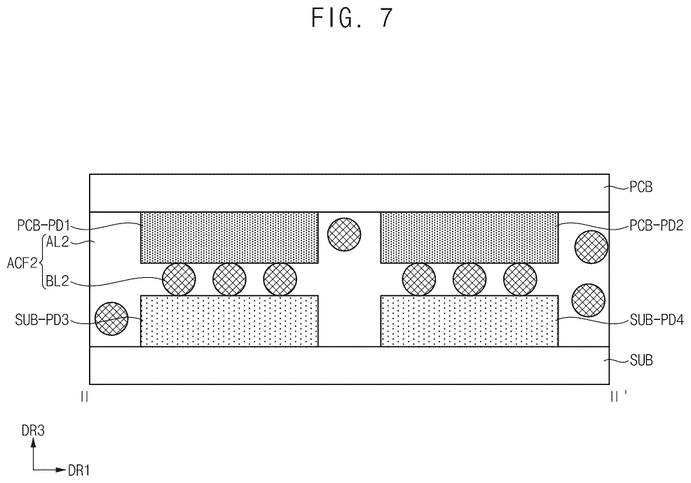

FIG. 5 is an enlarged plan view of an area A of FIG. 4. FIG. 6 is a cross-sectional view of the display unit of FIG. 5 taken along line I-I′. FIG. 7 is a cross-sectional view of the display unit of FIG. 5 taken along line II-II′.

Referring to FIG. 5, the display unit (e.g., the display unit DU of FIG. 2) may further include driving chip bonding portions IC-B and circuit board bonding portions PCB-B. The display panel DP and the driving chip IC may be attached to each other by the driving chip bonding portions IC-B. The display panel DP and the circuit board PCB may be attached to each other by the circuit board bonding portions PCB-B.

In FIG. 5, reference numerals are described for nine driving chip bonding portions among the driving chip bonding portions IC-B. For example, the driving chip bonding portions IC-B may include a first driving chip bonding portion CB1, a second driving chip bonding portion CB2, a third driving chip bonding portion CB3, a fourth driving chip bonding portion CB4, a fifth driving chip bonding portion CB5, a sixth driving chip bonding portion CB6, a seventh driving chip bonding portion CB7, an eighth driving chip bonding portion CB8, and a ninth driving chip bonding portion CB9. The driving chip bonding portions IC-B may be spaced apart from each other in a plan view. For example, the first driving chip bonding portion CB1, the second driving chip bonding portion CB2, the third driving chip bonding portion CB3, the fourth driving chip bonding portion CB4, the fifth driving chip bonding portion CB5, the sixth driving chip bonding portion CB6, the seventh driving chip bonding portion CB7, the eighth driving chip bonding portion CB8, and the ninth driving chip bonding portion CB9 may be spaced apart from each other in a plan view.

The second driving chip bonding portion CB2 may be adjacent to the first driving chip bonding portion CB1. For example, the second driving chip bonding portion CB2 may be adjacent to the first driving chip bonding portion CB1 in the first direction DR1. The third driving chip bonding portion CB3 may be adjacent to the second driving chip bonding portion CB2. For example, the third driving chip bonding portion CB3 may be adjacent to the second driving chip bonding portion CB2 in the first direction DR1. The fourth driving chip bonding portion CB4 may be adjacent to the third driving chip bonding portion CB3. For example, the fourth driving chip bonding portion CB4 may be adjacent to the third driving chip bonding portion CB3 in the first direction DR1. The sixth driving chip bonding portion CB6 may be adjacent to the fifth driving chip bonding portion CB5. For example, the sixth driving chip bonding portion CB6 may be adjacent to the fifth driving chip bonding portion CB5 in the first direction DR1. The seventh driving chip bonding portion CB7 may be adjacent to the sixth driving chip bonding portion CB6. For example, the seventh driving chip bonding portion CB7 may be adjacent to the sixth driving chip bonding portion CB6 in the first direction DR1. The eighth driving chip bonding portion CB8 may be adjacent to the seventh driving chip bonding portion CB7. For example, the eighth driving chip bonding portion CB8 may be adjacent to the seventh driving chip bonding portion CB7 in the first direction DR1.

In one or more embodiments, the first driving chip bonding portion CB1 may be located at an outermost portion of the driving chip bonding portions IC-B. For example, the first driving chip bonding portion CB1 may be located at an outermost portion of the driving chip bonding portions IC-B in the first direction DR1 and the second direction DR2. For example, the first driving chip bonding portion CB1 may be located at a left lower end of the driving chip IC in a plan view. In one or more embodiments, the eighth driving chip bonding portion CB8 may be located at an outermost portion of the driving chip bonding portions IC-B. For example, the eighth driving chip bonding portion CB8 may be located at an outermost portion of the driving chip bonding portions IC-B in the first direction DR1 and the second direction DR2. For example, the eighth driving chip bonding portion CB8 may be located at a right lower end of the driving chip IC in a plan view.

In one or more embodiments, some of the driving chip bonding portions IC-B may be electrically connected to the display area (e.g., the display area DA of FIG. 4). For example, the some of the driving chip bonding portions IC-B may be electrically connected to the pixels. In addition, the driving chip IC may be electrically connected to the driving chip bonding portions IC-B. Accordingly, the driving chip IC may provide the analog data signal to the pixels through the some of the driving chip bonding portions IC-B. For example, the ninth driving chip bonding portion CB9 may be electrically connected to the pixels, and the driving chip IC may provide the analog data signal to the pixels through the ninth driving chip bonding portion CB9.

In one or more embodiments, others of the driving chip bonding portions IC-B may be electrically separated from the display area. For example, the others of the driving chip bonding portions IC-B may be electrically separated from the pixels. For example, each of the first driving chip bonding portion CB1, the second driving chip bonding portion CB2, the third driving chip bonding portion CB3, the fourth driving chip bonding portion CB4, the fifth driving chip bonding portion CB5, the sixth driving chip bonding portion CB6, the seventh driving chip bonding portion CB7, and the eighth driving chip bonding portion CB8 may be electrically separated from the display area. Each of the first driving chip bonding portion CB1, the second driving chip bonding portion CB2, the third driving chip bonding portion CB3, the fourth driving chip bonding portion CB4, the fifth driving chip bonding portion CB5, the sixth driving chip bonding portion CB6, the seventh driving chip bonding portion CB7, and the eighth driving chip bonding portion CB8 is a component for measuring resistance of some of the driving chip bonding portions IC-B, and may not provide the analog data signal to the display area.

Hereinafter, cross-sectional structures of the fifth driving chip bonding portion CB5 and the sixth driving chip bonding portion CB6 will be described with reference to FIG. 6. Each of the driving chip bonding portions IC-B may have a same (or substantially the same) cross-sectional structure as cross-sectional structure of the fifth driving chip bonding portion CB5 and the sixth driving chip bonding portion CB6 described with reference to FIG. 6.

Referring further to FIG. 6, a first substrate pad SUB-PD1 and a second substrate pad SUB-PD2 may be located on the substrate SUB. Each of the first substrate pad SUB-PD1 and the second substrate pad SUB-PD2 may contact the substrate SUB in the third direction DR3. For example, each of the first substrate pad SUB-PD1 and the second substrate pad SUB-PD2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

A first driving chip pad IC-PD1 and a second driving chip pad IC-PD2 may be located under the driving chip IC. For example, each of the first driving chip pad IC-PD1 and the second driving chip pad IC-PD2 may be contact the driving chip IC in a direction opposite to the third direction DR3 and may be electrically connected to the driving chip IC. For example, each of the first driving chip pad IC-PD1 and the second driving chip pad IC-PD2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The first substrate pad SUB-PD1 and the second substrate pad SUB-PD2 may be attached to the driving chip IC through a first conductive film ACF1. For example, the first substrate pad SUB-PD1 may be attached to and electrically connected to the first driving chip pad IC-PD1 through the first conductive film ACF1. In addition, the second substrate pad SUB-PD2 may be attached to and electrically connected to the second driving chip pad IC-PD2 through the first conductive film ACF1.

The first conductive film ACF1 may include a first adhesive member AL1 and first conductive balls BL1. The first adhesive member AL1 may include an insulating polymer. For example, the first adhesive member AL1 may include an epoxy resin, an acrylic resin, and/or the like. These materials may be used alone or in combination with each other. Each of the first conductive balls BL1 may include a conductive particulate. For example, the conductive particulate may include a first portion (e.g., a core portion) and a second portion surrounding (or covering) the first portion. Each of the first portion and the second portion may include a metal, a metal oxide, a metal nitride, and/or the like. These materials may be used alone or in combination with each other.

The fifth driving chip bonding portion CB5 may include the first substrate pad SUB-PD1, the first driving chip pad IC-PD1, and a portion of the first conductive film ACF1 overlapping the first substrate pad SUB-PD1 (or, the first driving chip pad IC-PD1) in a plan view. The sixth driving chip bonding portion CB6 may include the second substrate pad SUB-PD2, the second driving chip pad IC-PD2, and a portion of the first conductive film ACF1 overlapping the second substrate pad SUB-PD2 (or, the second driving chip pad IC-PD2) in a plan view.

Referring back to FIG. 5, in one or more embodiments, the second driving chip bonding portion CB2 and the third driving chip bonding portion CB3 may be electrically connected to each other through a first bridge line BR1. In addition, the sixth driving chip bonding portion CB6 and the seventh driving chip bonding portion CB7 may be electrically connected to each other through a second bridge line BR2.

The circuit board bonding portions PCB-B may include a first circuit board bonding portion PB1, a second circuit board bonding portion PB2, a third circuit board bonding portion PB3, a fourth circuit board bonding portion PB4, a fifth circuit board bonding portion PB5, a sixth circuit board bonding portion PB6, a seventh circuit board bonding portion PB7, an eighth circuit board bonding portion PB8, a ninth circuit board bonding portion PB9, a tenth circuit board bonding portion PB10, an eleventh circuit board bonding portion PB11, a twelfth circuit board bonding portion PB12, a thirteenth circuit board bonding portion PB13, a fourteenth circuit board bonding portion PB14, a fifteenth circuit board bonding portion PB15, a sixteenth circuit board bonding portion PB16, and a seventeenth circuit board bonding portion PB17. The circuit board bonding portions PCB-B may be spaced apart from each other in a plan view. For example, the first circuit board bonding portion PB1, the second circuit board bonding portion PB2, the third circuit board bonding portion PB3, the fourth circuit board bonding portion PB4, the fifth circuit board bonding portion PB5, the sixth circuit board bonding portion PB6, the seventh circuit board bonding portion PB7, the eighth circuit board bonding portion PB8, the ninth circuit board bonding portion PB9, the tenth circuit board bonding portion PB10, the eleventh circuit board bonding portion PB11, the twelfth circuit board bonding portion PB12, the thirteenth circuit board bonding portion PB13, the fourteenth circuit board bonding portion PB14, the fifteenth circuit board bonding portion PB15, the sixteenth circuit board bonding portion PB16, and the seventeenth circuit board bonding portion PB17 may be spaced apart from each other in a plan view.

The second circuit board bonding portion PB2 may be adjacent to the first circuit board bonding portion PB1. For example, the second circuit board bonding portion PB2 may be adjacent to the first circuit board bonding portion PB1 in the first direction DR1. The third circuit board bonding portion PB3 may be adjacent to the second circuit board bonding portion PB2. For example, the third circuit board bonding portion PB3 may be adjacent to the second circuit board bonding portion PB2 in the first direction DR1. The fourth circuit board bonding portion PB4 may be adjacent to the third circuit board bonding portion PB3. For example, the fourth circuit board bonding portion PB4 may be adjacent to the third circuit board bonding portion PB3 in the first direction DR1. The fifth circuit board bonding portion PB5 may be adjacent to the fourth circuit board bonding portion PB4. For example, the fifth circuit board bonding portion PB5 may be adjacent to the fourth circuit board bonding portion PB4 in the first direction DR1. The sixth circuit board bonding portion PB6 may be adjacent to the fifth circuit board bonding portion PB5. For example, the sixth circuit board bonding portion PB6 may be adjacent to the fifth circuit board bonding portion PB5 in the first direction DR1. The seventh circuit board bonding portion PB7 may be adjacent to the sixth circuit board bonding portion PB6. For example, the seventh circuit board bonding portion PB7 may be adjacent to the sixth circuit board bonding portion PB6 in the first direction DR1. The eighth circuit board bonding portion PB8 may be adjacent to the seventh circuit board bonding portion PB7. For example, the eighth circuit board bonding portion PB8 may be adjacent to the seventh circuit board bonding portion PB7 in the first direction DR1. The tenth circuit board bonding portion PB10 may be adjacent to the ninth circuit board bonding portion PB9. For example, the tenth circuit board bonding portion PB10 may be adjacent to the ninth circuit board bonding portion PB9 in the first direction DR1. The eleventh circuit board bonding portion PB11 may be adjacent to the tenth circuit board bonding portion PB10. For example, the eleventh circuit board bonding portion PB11 may be adjacent to the tenth circuit board bonding portion PB10 in the first direction DR1. The twelfth circuit board bonding portion PB12 may be adjacent to the eleventh circuit board bonding portion PB11. For example, the twelfth circuit board bonding portion PB12 may be adjacent to the eleventh circuit board bonding portion PB11 in the first direction DR1. The thirteenth circuit board bonding portion PB13 may be adjacent to the twelfth circuit board bonding portion PB12. For example, the thirteenth circuit board bonding portion PB13 may be adjacent to the twelfth circuit board bonding portion PB12 in the first direction DR1. The fourteenth circuit board bonding portion PB14 may be adjacent to the thirteenth circuit board bonding portion PB13. For example, the fourteenth circuit board bonding portion PB14 may be adjacent to the thirteenth circuit board bonding portion PB13 in the first direction DR1. The fifteenth circuit board bonding portion PB15 may be adjacent to the fourteenth circuit board bonding portion PB14. For example, the fifteenth circuit board bonding portion PB15 may be adjacent to the fourteenth circuit board bonding portion PB14 in the first direction DR1. The sixteenth circuit board bonding portion PB16 may be adjacent to the fifteenth circuit board bonding portion PB15. For example, the sixteenth circuit board bonding portion PB16 may be adjacent to the fifteenth circuit board bonding portion PB15 in the first direction DR1.

In one or more embodiments, the first circuit board bonding portion PB1 may be located at an outermost portion of the circuit board bonding portions PCB-B. For example, the first circuit board bonding portion PB1 may be located at an outermost portion of the circuit board bonding portions PCB-B in the first direction DR1. For example, the first circuit board bonding portion PB1 may be located at a left side of the circuit board PCB in a plan view. In one or more embodiments, the sixteenth circuit board bonding portion PB16 may be located at an outermost portion of the circuit board bonding portions PCB-B. For example, the sixteenth circuit board bonding portion PB16 may be located at an outermost portion of the circuit board bonding portions PCB-B in the first direction DR1. For example, the sixteenth circuit board bonding portion PB16 may be located at a right side of the circuit board PCB in a plan view.

In one or more embodiments, some of the circuit board bonding portions PCB-B may be electrically connected to the driving chip IC. In addition, the circuit board PCB may be electrically connected to the circuit board bonding portions PCB-B. Accordingly, the circuit board PCB may provide the driving signal, the driving voltage, and/or the like to the driving chip IC through the some of the circuit board bonding portions PCB-B. For example, the seventeenth circuit board bonding portion PB17 may be electrically connected to the driving chip IC, and the circuit board PCB may provide the driving signal, the driving voltage, and/or the like to the driving chip IC through the seventeenth circuit board bonding portion PB17. For example, the circuit board PCB may provide the driving signal, the driving voltage, and/or the like to the driving chip IC through the seventeenth circuit board bonding portion PB17 and the ninth driving chip bonding portion CB9. In addition, each of the fifth circuit board bonding portion PB5, the sixth circuit board bonding portion PB6, the seventh circuit board bonding portion PB7, the eighth circuit board bonding portion PB8, the ninth circuit board bonding portion PB9, the tenth circuit board bonding portion PB10, the eleventh circuit board bonding portion PB11, and the twelfth circuit board bonding portion PB12 may be electrically connected to the driving chip IC. In one or more embodiments, the circuit board PCB may not provide the driving signal, the driving voltage, and/or the like to the driving chip IC through the fifth circuit board bonding portion PB5, the sixth circuit board bonding portion PB6, the seventh circuit board bonding portion PB7, the eighth circuit board bonding portion PB8, the ninth circuit board bonding portion PB9, the tenth circuit board bonding portion PB10, the eleventh circuit board bonding portion PB11, and the twelfth circuit board bonding portion PB12.

In one or more embodiments, others of the circuit board bonding portions PCB-B may be electrically separated from each of the driving chip IC and the display area. For example, the others of the circuit board bonding portions PCB-B may be electrically separated from each of the driving chip IC and the pixels. For example, each of the first circuit board bonding portion PB1, the second circuit board bonding portion PB2, the third circuit board bonding portion PB3, the fourth circuit board bonding portion PB4, the thirteenth circuit board bonding portion PB13, the fourteenth circuit board bonding portion PB14, the fifteenth circuit board bonding portion PB15, and the sixteenth circuit board bonding portion PB16 may be electrically separated from the driving chip IC and the display area. Each of the first circuit board bonding portion PB1, the second circuit board bonding portion PB2, the third circuit board bonding portion PB3, the fourth circuit board bonding portion PB4, the thirteenth circuit board bonding portion PB13, the fourteenth circuit board bonding portion PB14, the fifteenth circuit board bonding portion PB15, and the sixteenth circuit board bonding portion PB16 may be a component for measuring resistance of some of the circuit board bonding portions PCB-B, and may not provide the driving signal, the driving voltage, and/or the like to the driving chip IC and the display area.

Hereinafter, cross-sectional structures of the ninth circuit board bonding portion PB9 and the tenth circuit board bonding portion PB10 will be described with reference to FIG. 7. Each of the circuit board bonding portions PCB-B may have the same (or substantially the same) cross-sectional structure as a cross-sectional view of the ninth circuit board bonding portion PC9 and the tenth circuit board bonding portion PB10 described with reference to FIG. 7.

Referring further to FIG. 7, a third substrate pad SUB-PD3 and a fourth substrate pad SUB-PD4 may be located on the substrate SUB. Each of the third substrate pad SUB-PD3 and the fourth substrate pad SUB-PD4 may contact with the substrate SUB in the third direction DR3. For example, each of the third substrate pad SUB-PD3 and the fourth substrate pad SUB-PD4 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

A first circuit board pad PCB-PD1 and a second circuit board pad PCB-PD2 may be located under the circuit board PCB. For example, each of the first circuit board pad PCB-PD1 and the second circuit board pad PCB-PD2 may contact the circuit board PCB in a direction opposite to the third direction DR3 and may be electrically connected to the circuit board PCB. For example, each of the first circuit board pad PCB-PD1 and the second circuit board pad PCB-PD2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The third substrate pad SUB-PD3 and the fourth substrate pad SUB-PD4 may be attached to the circuit board PCB through a second conductive film ACF2. For example, the third substrate pad SUB-PD3 may be attached to and electrically connected to the first circuit board pad PCB-PD1 through the second conductive film ACF2. In addition, the fourth substrate pad SUB-PD4 may be attached to and electrically connected to the second circuit board pad PCB-PD2 through the second conductive film ACF2.

The second conductive film ACF2 may include a second adhesive member AL2 and second conductive balls BL2. The second adhesive member AL2 may include an insulating polymer. For example, the second adhesive member AL2 may include an epoxy resin, an acrylic resin, and/or the like. These materials may be used alone or in combination with each other. Each of the second conductive balls BL2 may include a conductive particulate. For example, the conductive particulate may include a first portion (e.g., a core portion) and a second portion surrounding (or covering) the first portion. Each of the first portion and the second portion may include a metal, a metal oxide, a metal nitride, and/or the like. These materials may be used alone or in combination with each other.

The ninth circuit board bonding portion PB9 may include the third substrate pad SUB-PD3, the first circuit board pad PCB-PD1, and a portion of the second conductive film ACF2 overlapping the third substrate pad SUB-PD3 (or, the first circuit board pad PCB-PD1) in a plan view. The tenth circuit board bonding portion PB10 may include the fourth substrate pad SUB-PD4, the second circuit board pad PCB-PD2, and a portion of the second conductive film ACF2 overlapping the fourth substrate pad SUB-PD4 (or, the second circuit board pad PCB-PD2) in a plan view.

Referring back to FIG. 5, in one or more embodiments, the second circuit board bonding portion PB2 and the third circuit board bonding portion PB3 may be electrically connected to each other through a third bridge line BR3. In addition, the fourteenth circuit board bonding portion PB14 and the fifteenth circuit board bonding portion PB15 may be electrically connected to each other through a fourth bridge line BR4.

In one or more embodiments, the connector CNT may be electrically connected to at least some of the circuit board bonding portions PCB-B. For example, the connector CNT may be electrically connected to a first circuit board bonding portion PB1 through a first wire L1. The connector CNT may be electrically connected to a second circuit board bonding portion PB2 through a second wire L2. The connector CNT may be electrically connected to a third circuit board bonding portion PB3 through a third wire L3. The connector CNT may be electrically connected to a fourth circuit board bonding portion PB4 through a fourth wire L4. The connector CNT may be electrically connected to a fifth circuit board bonding portion PB5 through a fifth wire L5. The connector CNT may be electrically connected to a sixth circuit board bonding portion PB6 through a sixth wire L6. The connector CNT may be electrically connected to a seventh circuit board bonding portion PB7 through a seventh wire L7. The connector CNT may be electrically connected to an eighth circuit board bonding portion PB8 through an eighth wire L8. The connector CNT may be electrically connected to a ninth circuit board bonding portion PB9 through a ninth wire L9. The connector CNT may be electrically connected to a tenth circuit board bonding portion PB10 through a tenth wire L10. The connector CNT may be electrically connected to an eleventh circuit board bonding portion PB11 through an eleventh wire L11. The connector CNT may be electrically connected to a twelfth circuit board bonding portion PB12 through a twelfth wire L12. The connector CNT may be electrically connected to a thirteenth circuit board bonding portion PB13 through a thirteenth wire L13. The connector CNT may be electrically connected to a fourteenth circuit board bonding portion PB14 through a fourteenth wire L14. The connector CNT may be electrically connected to a fifteenth circuit board bonding portion PB15 through a fifteenth wire L15. The connector CNT may be electrically connected to a sixteenth circuit board bonding portion PB16 through a sixteenth wire L16. The connector CNT may be electrically connected to a seventeenth circuit board bonding portion PB17 through a seventeenth wire L17.

Each of the first wire L1, the second wire L2, the third wire L3, the fourth wire L4, the fifth wire L5, the sixth wire L6, the seventh wire L7, the eighth wire L8, the ninth wire L9, the tenth wire L10, the eleventh wire L11, the twelfth wire L12, the thirteenth wire L13, the fourteenth wire L14, the fifteenth wire L15, the sixteenth wire L16, and the seventeenth wire L17 may be located on the circuit board PCB. Each of the first wire L1, the second wire L2, the third wire L3, the fourth wire L4, the fifth wire L5, the sixth wire L6, the seventh wire L7, the eighth wire L8, the ninth wire L9, the tenth wire L10, the eleventh wire L11, the twelfth wire L12, the thirteenth wire L13, the fourteenth wire L14, the fifteenth wire L15, the sixteenth wire L16, and the seventeenth wire L17 may be electrically connected to a corresponding circuit board pad of circuit board pads. For example, the ninth wire L9 may be electrically connected to the first circuit board pad (e.g., the first circuit board pad PCB-PD1 of FIG. 7), and the tenth wire L10 may be electrically connected to the second circuit board pad (for example, the second circuit board pad PCB-PD2 of FIG. 7).

In one or more embodiments, the connector CNT may be electrically connected to at least some of the driving chip bonding portions IC-B. For example, the connector CNT may be electrically connected to the first driving chip bonding portion CB1 through the fifth wire L5, the fifth circuit board bonding portion PB5, and an eighteenth wire L18. The connector CNT may be electrically connected to the second driving chip bonding portion CB2 through the sixth wire L6, the sixth circuit board bonding portion PB6, and a nineteenth wire L19. The connector CNT may be electrically connected to the third driving chip bonding portion CB3 through the seventh wire L7, the seventh circuit board bonding portion PB7, and a twentieth wire L20. The connector CNT may be electrically connected to the fourth driving chip bonding portion CB4 through the eighth wire L8, the eighth circuit board bonding portion PB8, and a twenty-first wire L21. The connector CNT may be electrically connected to the fifth driving chip bonding portion CB5 through the ninth wire L9, the ninth circuit board bonding portion PB9, and a twenty-second wire L22. The connector CNT may be electrically connected to the sixth driving chip bonding portion CB6 through the tenth wire L10, the tenth circuit board bonding portion PB10, and a twenty-third wire L23. The connector CNT may be electrically connected to the seventh driving chip bonding portion CB7 through the eleventh wire L11, the eleventh circuit board bonding portion PB11, and a twenty-fourth wire L24. The connector CNT may be electrically connected to the eighth driving chip bonding portion CB8 through the twelfth wire L12, the twelfth circuit board bonding portion PB12, and a twenty-fifth wire L25. The connector CNT may be electrically connected to the ninth driving chip bonding portion CB9 through the seventeenth wire L17, the seventeenth circuit board bonding portion PB17, and the twenty-sixth wire L26.

Each of the eighteenth wire L18, the nineteenth wire L19, the twentieth wire L20, the twenty-first wire L21, the twenty-second wire L22, the twenty-third wire L23, the twenty-fourth wire L24, the twenty-fifth wire L25, and the twenty-sixth wire L26 may be located on the display panel DP. Each of the eighteenth wire L18, the nineteenth wire L19, the twentieth wire L20, the twenty-first wire L21, the twenty-second wire L22, the twenty-third wire L23, the twenty-fourth wire L24, the twenty-fifth wire L25, and the twenty-sixth wire L26 may be electrically connected to the corresponding substrate pad of the substrate pads located on the substrate (e.g., the substrate SUB of FIG. 6). For example, the twenty-second wire L22 may be electrically connected to the first substrate pad (e.g., the first substrate pad SUB-PD1 of FIG. 6) and the third substrate pad (e.g., the third substrate pad SUB-PD3 of FIG. 7). The twenty-third wire L23 may be electrically connected to the second substrate pad (e.g., the second substrate pad SUB-PD2 of FIG. 6) and the fourth substrate pad (e.g., the fourth substrate pad SUB-PD4 of FIG. 7).

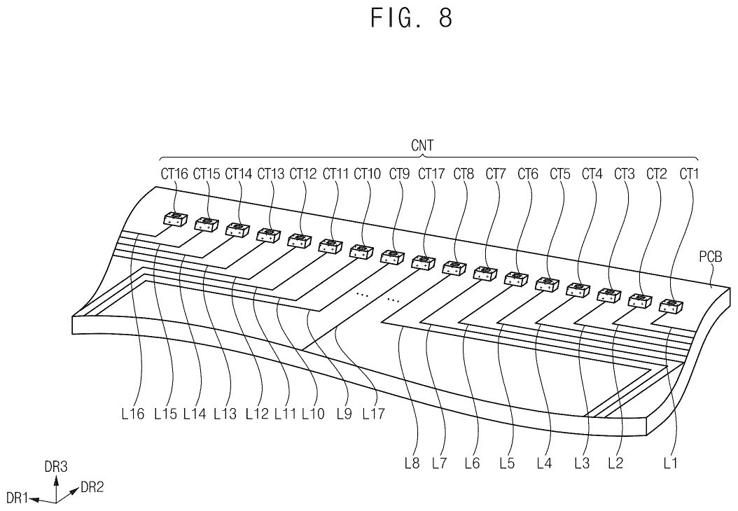

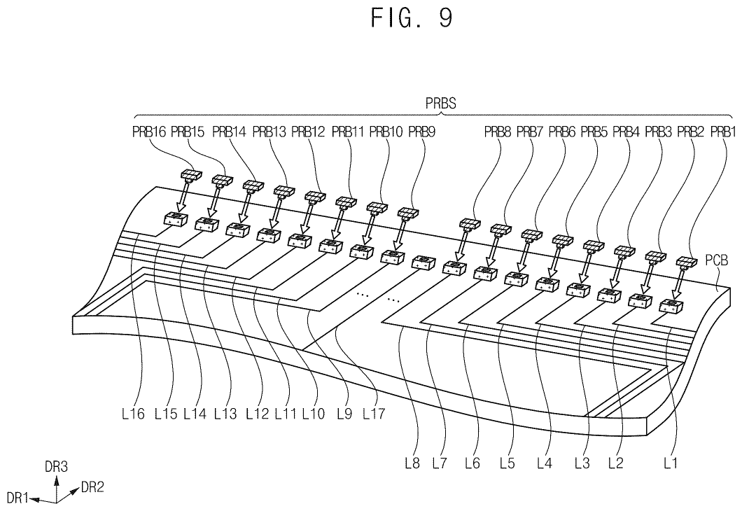

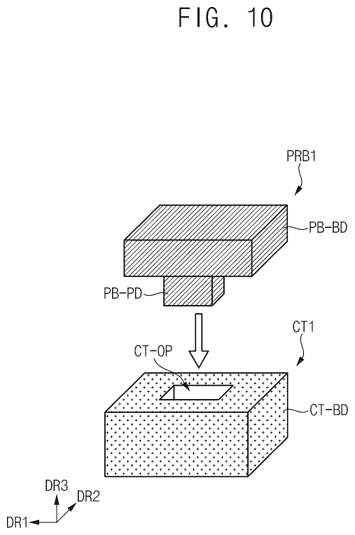

FIG. 8 is a perspective view illustrating a portion of the circuit board of FIG. 5 and a connector. FIG. 9 is a perspective view illustrating that probes are coupled to the connector of FIG. 8. FIG. 10 is a perspective view illustrating that a first probe is coupled to a first terminal of the connector of FIG. 9.

For convenience of explanation, reference numerals for the terminals CT1, CT2, CT3, CT4, CT5, CT6, CT7, CT8, CT9, CT10, CT11, CT12, CT13, CT14, CT15, CT16, and CT17 included in the connector CNT of FIG. 8 may be omitted in FIG. 9.

Referring to FIGS. 5 and 8, the connector CNT may include terminals. For example, the connector CNT may include a first terminal CT1, a second terminal CT2, a third terminal CT3, a fourth terminal CT4, a fifth terminal CT5, a sixth terminal CT6, a seventh terminal CT7, an eighth terminal CT8, a ninth terminal CT9, a tenth terminal CT10, an eleventh terminal CT11, a twelfth terminal CT12, a thirteenth terminal CT13, a fourteenth terminal CT14, a fifteenth terminal CT15, a sixteenth terminal CT16, and a seventeenth terminal CT17. The connector CNT may refer to a set of the terminals. The first terminal CT1, the second terminal CT2, the third terminal CT3, the fourth terminal CT4, the fifth terminal CT5, the sixth terminal CT6, the seventh terminal CT7, the eighth terminal CT8, the ninth terminal CT9, the tenth terminal CT10, the eleventh terminal CT11, the twelfth terminal CT12, the thirteenth terminal CT13, the fourteenth terminal CT14, the fifteenth terminal CT15, the sixteenth terminal CT16, and the seventeenth terminal CT17 may be spaced apart from each other in a plan view. Each of the terminals included in the connector CNT may protrude from the circuit board PCB in the third direction DR3. The terminals may be repeatedly arranged along the first direction DR1. FIG. 8 may illustrate an example in which the connector CNT includes seventeen terminals. However, embodiments according to the present disclosure are not necessarily limited thereto, and a number of terminals included in the connector CNT may vary according to various embodiments.

The first terminal CT1 may be electrically connected to the first wire L1. For example, the first terminal CT1 may be electrically connected to the first circuit board bonding portion PB1 through the first wire L1. The second terminal CT2 may be electrically connected to the second wire L2. For example, the second terminal CT2 may be electrically connected to the second circuit board bonding portion PB2 through the second wire L2. The third terminal CT3 may be electrically connected to the third wire L3. For example, the third terminal CT3 may be electrically connected to the third circuit board bonding portion PB3 through the third wire L3. The fourth terminal CT4 may be electrically connected to the fourth wire L4. For example, the fourth terminal CT4 may be electrically connected to the fourth circuit board bonding portion PB4 through the fourth wire L4. The fifth terminal CT5 may be electrically connected to the fifth wire L5. For example, the fifth terminal CT5 may be electrically connected to the fifth circuit board bonding portion PB5 through the fifth wire L5. The sixth terminal CT6 may be electrically connected to the sixth wire L6. For example, the sixth terminal CT6 may be electrically connected to the sixth circuit board bonding portion PB6 through the sixth wire L6. The seventh terminal CT7 may be electrically connected to the seventh wire L7. For example, the seventh terminal CT7 may be electrically connected to the seventh circuit board bonding portion PB7 through the seventh wire L7. The eighth terminal CT8 may be electrically connected to the eighth wire L8. For example, the eighth terminal CT8 may be electrically connected to the eighth circuit board bonding portion PB8 through the eighth wire L8. The ninth terminal CT9 may be electrically connected to the ninth wire L9. For example, the ninth terminal CT9 may be electrically connected to the ninth circuit board bonding portion PB9 through the ninth wire L9. The tenth terminal CT10 may be electrically connected to the tenth wire L10. For example, the tenth terminal CT10 may be electrically connected to the tenth circuit board bonding portion PB10 through the tenth wire L10. The eleventh terminal CT11 may be electrically connected to the eleventh wire L11. For example, the eleventh terminal CT11 may be electrically connected to the eleventh circuit board bonding portion PB11 through the eleventh wire L11. The twelfth terminal CT12 may be electrically connected to the twelfth wire L12. For example, the twelfth terminal CT12 may be electrically connected to the twelfth circuit board bonding portion PB12 through the twelfth wire L12. The thirteenth terminal CT13 may be electrically connected to the thirteenth wire L13. For example, the thirteenth terminal CT13 may be electrically connected to the thirteenth circuit board bonding portion PB13 through the thirteenth wire L13. The fourteenth terminal CT14 may be electrically connected to the fourteenth wire L14. For example, the fourteenth terminal CT14 may be electrically connected to the fourteenth circuit board bonding portion PB14 through the fourteenth wire L14. The fifteenth terminal CT15 may be electrically connected to the fifteenth wire L15. For example, the fifteenth terminal CT15 may be electrically connected to the fifteenth circuit board bonding portion PB15 through the fifteenth wire L15. The sixteenth terminal CT16 may be electrically connected to the sixteenth wire L16. For example, the sixteenth terminal CT16 may be electrically connected to the sixteenth circuit board bonding portion PB16 through the sixteenth wire L16. The seventeenth terminal CT17 may be electrically connected to the seventeenth wire L17. For example, the seventeenth terminal CT17 may be electrically connected to the seventeenth circuit board bonding portion PB17 through the seventeenth wire L17.

Referring further to FIG. 9, probes PRBS may be provided to measure a resistance of the electronic device (e.g., the electronic device ED of FIG. 1). For example, a resistance of some of the driving chip bonding portions IC-B and a resistance of some of the circuit board bonding portions PCB-B may be measured using the probes PRBS. Each of the probes PRBS may be connected to a portion of the connector CNT. For example, each of the probes PRBS may be connected to a corresponding terminal of the terminals included in the connector CNT.

The probes PRBS may include a first probe PRB1, a second probe PRB2, a third probe PRB3, a fourth probe PRB4, a fifth probe PRB5, a sixth probe PRB6, a seventh probe PRB7, an eighth probe PRB8, a ninth probe PRB9, a tenth probe PRB10, an eleventh probe PRB11, a twelfth probe PRB12, a thirteenth probe PRB13, a fourteenth probe PRB14, a fifteenth probe PRB15, and a sixteenth probe PRB16.

The first probe PRB1 may be connected to the first terminal CT1. The second probe PRB2 may be connected to the second terminal CT2. The third probe PRB3 may be connected to the third terminal CT3. The fourth probe PRB4 may be connected to the fourth terminal CT4. The fifth probe PRB5 may be connected to the fifth terminal CT5. The sixth probe PRB6 may be connected to the sixth terminal CT6. The seventh probe PRB7 may be connected to the seventh terminal CT7. The eighth probe PRB8 may be connected to the eighth terminal CT8. The ninth probe PRB9 may be connected to the ninth terminal CT9. The tenth probe PRB10 may be connected to the tenth terminal CT10. The eleventh probe PRB11 may be connected to the eleventh terminal CT11. The twelfth probe PRB12 may be connected to the twelfth terminal CT12. The thirteenth probe PRB13 may be connected to the thirteenth terminal CT13. The fourteenth probe PRB14 may be connected to the fourteenth terminal CT14. The fifteenth probe PRB15 may be connected to the fifteenth terminal CT15. The sixteenth probe PRB16 may be connected to the sixteenth terminal CT16.

Referring further to FIG. 10, the first terminal CT1 may include a body portion CT-BD. The body portion CT-BD may include (or define) an insertion groove CT-OP. The insertion groove CT-OP may be a portion from which at least a portion of the body portion CT-BD is removed from an upper surface of the body portion CT-BD.

The first probe PRB1 may include a body portion PB-BD and an insertion portion PB-PD. The insertion portion PB-PD may be a portion protruding from the body portion PB-BD. For example, the insertion portion PB-PD may be a portion protruding from the body portion PB-BD in a direction opposite to the third direction DR3.

In one or more embodiments, the insertion groove CT-OP may receive the insertion portion PB-PD. For example, the insertion groove CT-OP and the insertion portion PB-PD may have the same (or substantially the same) shape. As the insertion portion PB-PD is received in the insertion groove CT-OP, the first probe PRB1 may be connected to the first terminal CT1.

Each of the probes PRBS may have the same (or substantially the same) shape as the first probe PRB1 of FIG. 10. In addition, each of the terminals included in the connector CNT may have the same (or substantially the same) shape as the first terminal CT1 of FIG. 10. In addition, a manner in which the first probe PRB1 is connected to the first terminal CT1 may not necessarily be limited to a method described with reference to FIG. 10. For example, the first probe PRB1 may be connected to the first terminal CT1 by a zero insertion force (“ZIF”) method.

Next, a method of measuring resistance of the electronic device (e.g., the electronic device ED of FIG. 1) according to one or more embodiments will be described.

Referring back to FIGS. 5, 8, and 9, a method of measuring resistance of the electronic device according to one or more embodiments may include measuring resistance of some of the driving chip bonding portions IC-B using probes PRBS and measuring resistance of some of the circuit board bonding portions PCB-B.

The measuring of resistance of at least some of the driving chip bonding portions IC-B may include applying current to the fifth probe PRB5 and the sixth probe PRB6. Accordingly, current may be applied to the first driving chip bonding portion CB1 and the second driving chip bonding portion CB2. For example, the fifth probe PRB5 and the sixth probe PRB6 may serve as a first terminal and a second terminal of an ammeter, respectively. The measuring of resistance of at least some of the driving chip bonding portions IC-B may further include applying voltage to the seventh probe PRB7 and the eighth probe PRB8. Accordingly, voltage may be applied to the third driving chip bonding portion CB3 and the fourth driving chip bonding portion CB4. For example, the seventh probe PRB7 and the eighth probe PRB8 may serve as a first terminal and a second terminal of a voltmeter, respectively. Accordingly, resistance of the second driving chip bonding portion CB2 and/or the third driving chip bonding portion CB3 may be measured. However, embodiments according to the present disclosure are not necessarily limited thereto, and functions of the fifth probe PRB5, the sixth probe PRB6, the seventh probe PRB7, and the eighth probe PRB8 (e.g., functions of a first terminal of an ammeter, a second terminal of an ammeter, a first terminal of a voltmeter, or a second terminal of a voltmeter) may vary depending on embodiments. Specific driving chip bonding portions of the driving chip bonding portions IC-B for which resistance is measured may also vary depending on embodiments.

The measuring of resistance of at least some of the driving chip bonding portions IC-B may further include applying current to the eleventh probe PRB11 and the twelfth probe PRB12. Accordingly, current may be applied to the seventh driving chip bonding portion CB7 and the eighth driving chip bonding portion CB8. For example, the eleventh probe PRB11 and the twelfth probe PRB12 may serve as a first terminal and a second terminal of an ammeter, respectively. The measuring of resistance of at least some of the driving chip bonding portions IC-B may further include applying voltage to the ninth probe PRB9 and the tenth probe PRB10. Accordingly, voltage may be applied to the fifth driving chip bonding portion CB5 and the sixth driving chip bonding portion CB6. For example, the ninth probe PRB9 and the tenth probe PRB10 may serve as a first terminal and a second terminal of a voltmeter, respectively. Accordingly, resistance of the sixth driving chip bonding portion CB6 and/or the seventh driving chip bonding portion CB7 may be measured. However, embodiments according to the present disclosure are not necessarily limited thereto, and functions of the ninth probe PRB9, the tenth probe PRB10, the eleventh probe PRB11, and the twelfth probe PRB12 (e.g., functions of a first terminal of an ammeter, a second terminal of an ammeter, a first terminal of a voltmeter, or a second terminal of a voltmeter) may vary depending on embodiments. Specific driving chip bonding portions of the driving chip bonding portions IC-B for which resistance is measured may also vary depending on embodiments.

The measuring of resistance of at least some of the circuit board bonding portions PCB-B may include applying current to the first probe PRB1 and the second probe PRB2. Accordingly, current may be applied to the first circuit board bonding portion PB1 and the second circuit board bonding portion PB2. For example, the first probe PRB1 and the second probe PRB2 may serve as a first terminal and a second terminal of an ammeter, respectively. The measuring of resistance of at least some of the circuit board bonding portions PCB-B may further include applying voltage to the third probe PRB3 and the fourth probe PRB4. Accordingly, voltage may be applied to the third circuit board bonding portion PB3 and the fourth circuit board bonding portion PB4. For example, the third probe PRB3 and the fourth probe PRB4 may serve as a first terminal and a second terminal of a voltmeter, respectively. Accordingly, resistance of the second circuit board bonding portion PB2 and/or the third circuit board bonding portion PB3 may be measured. However, embodiments according to the present disclosure are not necessarily limited thereto, and functions of the first probe PRB1, the second probe PRB2, the third probe PRB3, and the fourth probe PRB4 (e.g., functions of a first terminal of an ammeter, a second terminal of an ammeter, a first terminal of a voltmeter, or a second terminal of a voltmeter) may vary depending on embodiments. Specific circuit board bonding portions among the circuit board bonding portions PCB-B for which resistance is measured may also vary depending on embodiments.

The measuring of resistance of at least some of the circuit board bonding portions PCB-B may include applying current to the fifteenth probe PRB15 and the sixteenth probe PRB16. Accordingly, current may be applied to the fifteenth circuit board bonding portion PB15 and the sixteenth circuit board bonding portion PB16. For example, the fifteenth probe PRB15 and the sixteenth probe PRB16 may serve as a first terminal and a second terminal of an ammeter, respectively. The measuring of resistance of at least some of the circuit board bonding portions PCB-B may further include applying voltage to the thirteenth probe PRB13 and the fourteenth probe PRB14. Accordingly, voltage may be applied to the thirteenth circuit board bonding portion PB13 and the fourteenth circuit board bonding portion PB14. For example, the thirteenth probe PRB13 and the fourteenth probe PRB14 may serve as a first terminal and a second terminal of a voltmeter, respectively. Accordingly, resistance of the fourteenth circuit board bonding portion PB14 and/or the fifteenth circuit board bonding portion PB15 may be measured. However, embodiments according to the present disclosure are not necessarily limited thereto, and functions of the thirteenth probe PRB13, the fourteenth probe PRB14, the fifteenth probe PRB15, and the sixteenth probe PRB16 (e.g., functions of a first terminal of an ammeter, a second terminal of an ammeter, a first terminal of a voltmeter, or a second terminal of a voltmeter) may vary depending on embodiments. Specific circuit board bonding portions among the circuit board bonding portions PCB-B for which resistance is measured may also vary depending on embodiments.

After the measuring of the resistance of at least some of the driving chip bonding portions IC-B and the measuring of the resistance of at least some of the circuit board bonding portions PCB-B, the probes PRBS may be removed from the connector CNT. After the probes PRBS are removed from the connector CNT, the electronic module (e.g., the electronic module EM of FIG. 2) may be connected to the connector CNT. The electronic module may be electrically connected to the circuit board PCB through the connector CNT.

According to one or more embodiments of this disclosure, the resistance of the electronic device may be measured through the connector CNT. For example, the resistance of at least some of the circuit board bonding portions PCB-B may be measured through the connector CNT. In addition, the resistance of at least some of the driving chip bonding portions IC-B may be measured through the connector CNT. Accordingly, even if test pads are omitted in the circuit board PCB, the resistance of at least some of the circuit board bonding portions PCB-B and the resistance of at least some of the driving chip bonding portions IC-B may be measured. Accordingly, an area of the circuit board PCB may be relatively reduced, and instances of electrostatic discharge flowing into the circuit board PCB and the display panel DP through the test pads may be prevented or reduced. In addition, with respect to electronic devices that use a same connector, the probes PRBS for measuring the resistance of at least some of the driving chip bonding portions IC-B and at least some of the circuit board bonding portions PCB-B may not need to be replaced. For example, the probes PRBS may be shared among electronic devices that use the same connector.

FIG. 11 is a cross-sectional view illustrating a pixel included in the display panel of FIG. 4.

Referring to FIG. 11, the pixel PX may include a substrate SUB, a buffer layer BUF, a gate insulating layer GI, an interlayer insulating layer ILD, a via insulating layer VIA, a transistor TR, a light-emitting element LED, pixel defining layer PDL, and an encapsulating layer TFE.

The transistor TR may include an active layer ACT, a source electrode SE, a gate electrode GE, and a drain electrode DE. The light-emitting element LED may include a pixel electrode PE, a light-emitting layer EML, and a common electrode CE.

The substrate SUB may include a transparent material or an opaque material. The substrate SUB may be formed of a transparent resin substrate. Example of the transparent resin substrate may include a polyimide substrate. In this case, the polyimide substrate may include a first organic layer, a first barrier layer, a second organic layer, and/or the like.

Optionally, the substrate SUB may include a quartz substrate (e.g. a synthetic quartz substrate, a fluorine-doped quartz substrate), a calcium fluoride substrate, a sodalime glass substrate, a non-alkali glass substrate, and/or the like. These materials may be used alone or in combination with each other.

The buffer layer BUF may be located on the substrate SUB. The buffer layer BUF may prevent or reduce instances of metal atoms, contaminants, or impurities diffusing from the substrate SUB to the transistor TR. In addition, the buffer layer BUF can relatively improve flatness of a surface of the substrate SUB when the surface of the substrate SUB is not uniform.

For example, the buffer layer BUF may include an inorganic material such as silicon oxide, silicon nitride, silicon oxynitride, and/or the like. These materials may be used alone or in combination with each other.

The active layer ACT may be located on the buffer layer BUF. The active layer ACT may include an inorganic semiconductor (e.g., amorphous silicon, polysilicon, a metal oxide semiconductor,), an organic semiconductor, and/or the like. These materials may be used alone or in combination with each other. The active layer ACT may include a source area, a drain area, and a channel area located between the source area and the drain area.

The metal oxide semiconductor may include a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The gate insulating layer GI may be located on the buffer layer BUF. The gate insulating layer GI may sufficiently cover the active layer ACT. For example, the gate insulating layer GI may cover the active layer ACT and may be located along a profile of the active layer ACT.

For example, the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The gate electrode GE may be located on the gate insulating layer GI. The gate electrode GE may overlap the channel area of the active layer ACT in a plan view.

The gate electrode GE may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other.

Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The interlayer insulating layer ILD may be located on the gate insulating layer GI. The interlayer insulating layer ILD may sufficiently cover the gate electrode GE. For example, the interlayer insulating layer ILD may cover the gate electrode GE, and may be located along a profile of the gate electrode GE.

For example, the interlayer insulating layer ILD may include inorganic materials such as silicon oxide, silicon nitride, silicon carbide, silicon oxynitride, silicon oxycarbide, and/or the like. These materials may be used alone or in combination with each other.

The source electrode SE may be located on the interlayer insulating layer ILD. The source electrode SE may be connected to the source area of the active layer ACT through a contact hole penetrating the gate insulating layer GI and the interlayer insulating layer ILD.

The drain electrode DE may be located on the interlayer insulating layer ILD. The drain electrode DE may be connected to the drain area of the active layer ACT through a contact hole penetrating the gate insulating layer GI and the interlayer insulating layer ILD.

For example, the source electrode SE may include a metal, an alloy, a metal nitride, a conductive metal oxide, a transparent conductive material, and/or the like. These materials may be used alone or in combination with each other. The drain electrode DE and the source electrode SE may be formed through the same process and may include the same material.

The via insulating layer VIA may be located on the interlayer insulating layer ILD. The via insulating layer VIA may sufficiently cover the source electrode SE and the drain electrode DE. The via insulating layer VIA may include an organic material.

For example, the via insulating layer VIA may include organic materials such as phenolic resin, acrylic resin, polyimide resin, polyamide resin, siloxane resin, epoxy resin, and/or the like. These materials may be used alone or in combination with each other.

The pixel electrode PE may be located on the via insulating layer VIA. The pixel electrode PE may be connected to the drain electrode DE through a contact hole penetrating the via insulating layer VIA.

The pixel electrode PE may include a metal, an alloy, a metal nitride, a conductive metal oxide, a transparent conductive material, and/or the like. These materials be used alone or in combination with each other. In one or more embodiments, the pixel electrode PE may have a stacked structure including ITO/Ag/ITO. For example, the pixel electrode PE may operate as an anode of the light-emitting element LED.

The pixel defining layer PDL may be located on the via insulating layer VIA. The pixel defining layer PDL may cover side portions of the pixel electrode PE. In addition, an opening exposing a portion of the upper surface of the pixel electrode PE may be defined in the pixel defining layer PDL. For example, the pixel defining layer PDL may include an inorganic material or an organic material. In one or more embodiments, the pixel defining layer PDL may include an organic material such as an epoxy resin, a siloxane resin, and/or the like. These materials may be used alone or in combination with each other. According to some embodiments, the pixel defining layer PDL may further include a light blocking material containing a black pigment, a black dye, and/or the like.

The light-emitting layer EML may be located on the pixel electrode PE. The light-emitting layer EML may include an organic material that emits light of a color (e.g., a set or predetermined color). For example, the light-emitting layer EML may include an organic material that emits red light. However, embodiments according to the present disclosure are not limited thereto, and the light-emitting layer EML may emit light of a different color from red light.

The common electrode CE may be located on the light-emitting layer EML and the pixel defining layer PDL. The common electrode CE may include a metal, an alloy, a metal nitride, a conductive metal oxide, a transparent conductive material, and/or the like. These materials may be used alone or in combination with each other. The common electrode CE may operate as a cathode of the light-emitting element.

The encapsulation layer TFE may be located on the common electrode CE. The encapsulation layer TFE may prevent or reduce instances of contaminants such as impurities and moisture penetrating into the pixel electrode PE, the light-emitting layer EML, and the common electrode CE from the outside. The encapsulation layer TFE may include at least one inorganic layer and at least one organic layer.

For example, the inorganic layer may include silicon oxide, silicon nitride, silicon oxynitride, and/or the like. These materials may be used alone or in combination with each other. The organic layer may include a polymer cured product such as polyacrylate.

Although one or more embodiments of the pixel P has been described with reference to FIG. 4, the pixel is not necessarily limited to the structure illustrated in FIG. 11. For example, the pixel PX may include all structures that receive an electrical signal and emit light having a luminance corresponding to the intensity of the electrical signal.

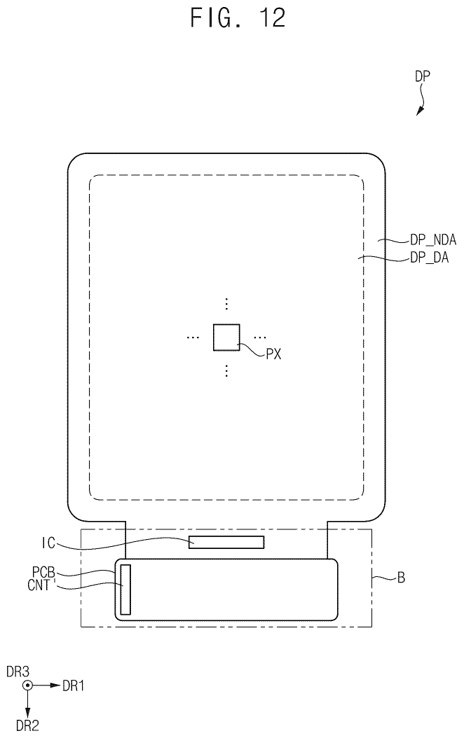

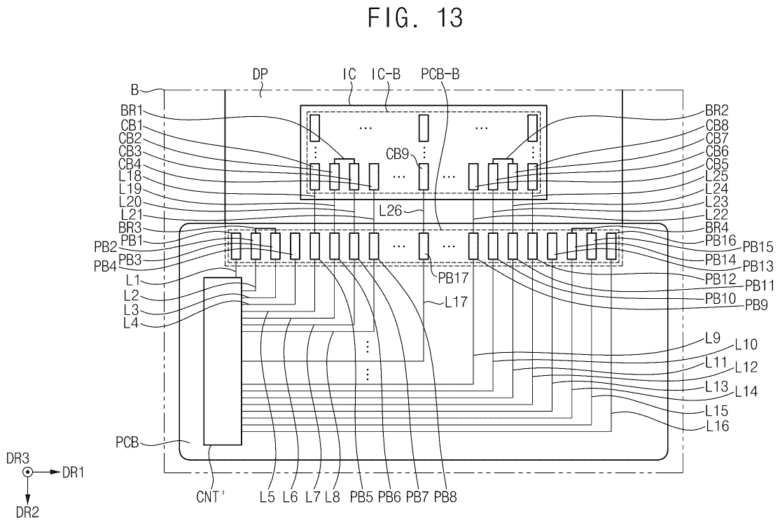

FIG. 12 is a plan view illustrating an example of some components included in the display unit included in the electronic device of FIG. 2. FIG. 13 is an enlarged plan view illustrating an area B of FIG. 12. The plan view of FIG. 12 may correspond (or substantially correspond) to the plan view of FIG. 4

The configurations illustrated in FIG. 12 may differ from configurations illustrated in FIG. 4 only in the connector CNT′. Accordingly, redundant descriptions may be omitted or simplified.

Referring to FIGS. 12 and 13, a position of the connector CNT′ of FIG. 12 may differ from a position of the connector CNT of FIG. 4. In addition, an arrangement direction of terminals included in the connector CNT′ may differ from an arrangement direction of the terminals included in the connector CNT of FIG. 4. In one or more embodiments, the connector CNT′ may be located on a left side of the circuit board PCB in a plan view. The connector CNT of FIG. 13 may include the terminals CT1, CT2, CT3, CT4, CT5, CT6, CT7, CT8, CT9, CT10, CT11, CT12, CT13, CT14, CT15, CT16, and CT17 of FIG. 8, and the terminals included in the connector CNT′ may be repeatedly arranged along the second direction DR2.

As illustrated in FIG. 13, as the position of the connector CNT′ differs from the position of the connector CNT of FIG. 4, and the arrangement direction of the terminals included in the connector CNT differs from the arrangement direction of the terminals included in the connector CNT of FIG. 4, a position and/or an extension direction of wires connecting the connector CNT′ and the circuit board bonding portions PCB-B to each other may differ from a position and/or an extension direction of wires connecting the connector CNT and the circuit board bonding portions PCB-B of FIG. 4 to each other. For example, a position and/or an extension direction of the first wire L1, the second wire L2, the third wire L3, the fourth wire L4, the fifth wire L5, the sixth wire L6, the seventh wire L7, the eighth wire L8, the ninth wire L9, the tenth wire L10, the eleventh wire L11, the twelfth wire L12, the thirteenth wire L13, the fourteenth wire L14, the fifteenth wire L15, the sixteenth wire L16, and the seventeenth wire L17 of FIG. 13 may differ from a position and/or an extension direction of the first wire L1, the second wire L2, the third wire L3, the fourth wire L4, the fifth wire L5, the sixth wire L6, the seventh wire L7, the eighth wire L8, the ninth wire L9, the tenth wire L10, the eleventh wire L11, the twelfth wire L12, the thirteenth wire L13, the fourteenth wire L14, the fifteenth wire L15, the sixteenth wire L16, and the seventeenth wire L17 of FIG. 5, respectively.

However, embodiments according to the present disclosure are not necessarily limited thereto, and the position of the connector CNT and the arrangement direction of the terminals may vary depending on embodiments. For example, the connector CNT may be located on a right side of the circuit board PCB.

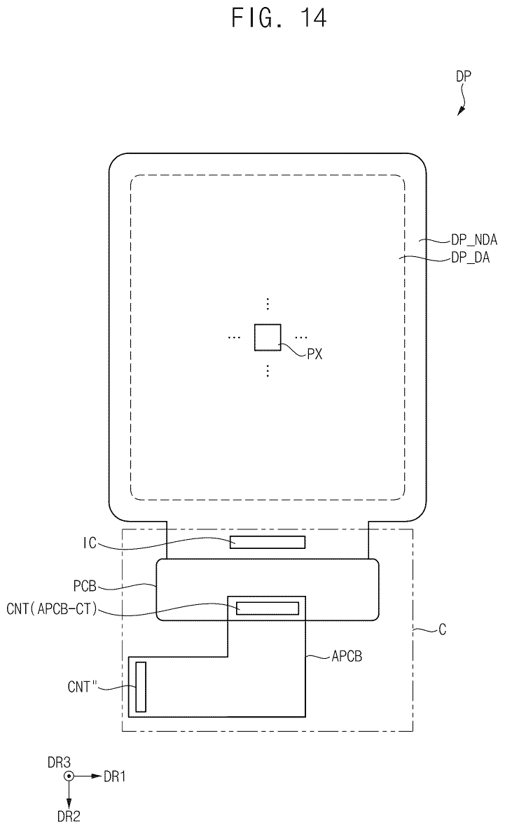

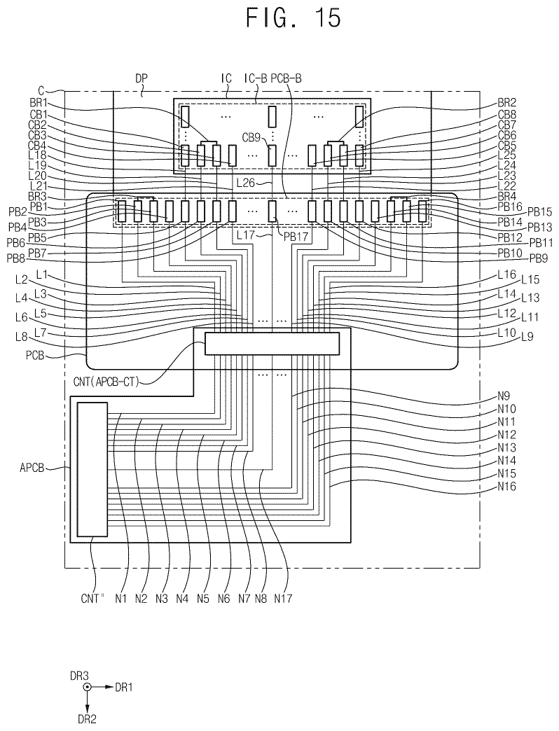

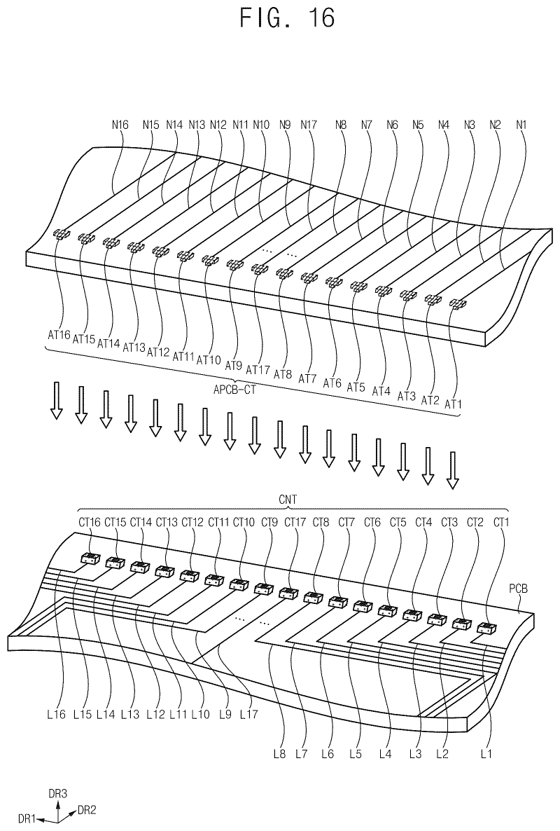

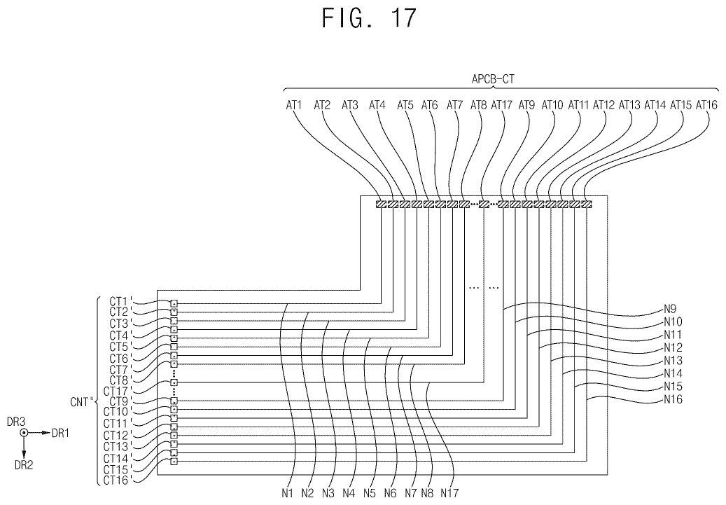

FIG. 14 is a plan view illustrating an example of some components included in the display unit included in the electronic device of FIG. 2. FIG. 15 is an enlarged plan view illustrating an area C of FIG. 14. FIG. 16 is a perspective view illustrating that an auxiliary circuit board is attached to the circuit board of FIG. 15. FIG. 17 is a plan view illustrating an auxiliary circuit board, an intermediate connector, and an auxiliary connector of FIG. 15. The plan view of FIG. 14 may correspond (or substantially correspond) to the plan view of FIG. 4.

Configurations illustrated in FIG. 14 may differ from configurations illustrated in FIG. 4 only in an auxiliary circuit board APCB, an intermediate connector APCB-CT, and an auxiliary connector CNT″ . Accordingly, redundant descriptions may be omitted or simplified.

Referring to FIG. 14, the display unit (e.g., the display unit DU of FIG. 2) may further include an auxiliary circuit board APCB, an intermediate connector APCB-CT, and an auxiliary connector CNT″.

The auxiliary circuit board APCB may be attached to one side of the circuit board PCB. For example, the auxiliary circuit board APCB may be attached to one side of the circuit board PCB through the intermediate connector APCB-CT. The auxiliary circuit board APCB may be electrically connected to the circuit board PCB through the intermediate connector APCB-CT. The auxiliary circuit board APCB may include a first portion and a second portion. The first portion may extend in the first direction DR1. The second portion may protrude from an end of the first portion. For example, the second portion may protrude from the end of the first portion in a direction opposite to a second direction DR2. The second portion may be a portion that directly contact the intermediate connector APCB-CT.

The auxiliary connector CNT″ may be located on one side of the auxiliary circuit board APCB. For example, the auxiliary connector CNT″ may be located on one side of the first portion of the auxiliary circuit board APCB. For example, the auxiliary connector CNT″ may be located on a left side of the first portion of the auxiliary circuit board APCB. However, embodiments according to the present disclosure are not necessarily limited thereto, and a position of the auxiliary connector CNT″ in a plan view may vary depending on embodiments.

Referring further to FIGS. 15, 16, and 17, the intermediate connector APCB-CT may include terminals. For example, the intermediate connector APCB-CT may include a first terminal AT1, a second terminal AT2, a third terminal AT3, a fourth terminal AT4, a fifth terminal AT5, a sixth terminal AT6, a seventh terminal AT7, an eighth terminal AT8, a ninth terminal AT9, a tenth terminal AT10, an eleventh terminal AT11, a twelfth terminal AT12, a thirteenth terminal AT13, a fourteenth terminal AT14, a fifteenth terminal AT15, a sixteenth terminal AT16, and a seventeenth terminal AT17. The intermediate connector APCB-CT may refer to a set of the terminals. The first terminal AT1, the second terminal AT2, the third terminal AT3, the fourth terminal AT4, the fifth terminal AT5, the sixth terminal AT6, the seventh terminal AT7, the eighth terminal AT8, the ninth terminal AT9, the tenth terminal AT10, the eleventh terminal AT11, the twelfth terminal AT12, the thirteenth terminal AT13, the fourteenth terminal AT14, the fifteenth terminal AT15, the sixteenth terminal AT16, and the seventeenth terminal AT17 may be spaced apart from each other in a plan view. Each of the terminals included in the intermediate connector APCB-CT may protrude from the auxiliary circuit board APCB in a direction opposite to the third direction DR3. The terminals may be arranged along the first direction DR1.

The intermediate connector APCB-CT may be connected to the connector CNT. For example, as illustrated in FIG. 16, each of the terminals included in the intermediate connector APCB-CT may be connected to a corresponding terminal of the terminals included in the connector CNT. For example, the first terminal AT1 may be connected to the first terminal CT1. The second terminal AT2 may be connected to the second terminal CT2. The third terminal AT3 may be connected to the third terminal CT3. The fourth terminal AT4 may be connected to the fourth terminal CT4. The fifth terminal AT5 may be connected to the fifth terminal CT5. The sixth terminal AT6 may be connected to the sixth terminal CT6. The seventh terminal AT7 may be connected to the seventh terminal CT7. The eighth terminal AT8 may be connected to the eighth terminal CT8. The ninth terminal AT9 may be connected to the ninth terminal CT9. The tenth terminal AT10 may be connected to the tenth terminal CT10. The eleventh terminal AT11 may be connected to the eleventh terminal CT11. The twelfth terminal AT12 may be connected to the twelfth terminal CT12. The thirteenth terminal AT13 may be connected to the thirteenth terminal CT13. The fourteenth terminal AT14 may be connected to the fourteenth terminal CT14. The fifteenth terminal AT15 may be connected to the fifteenth terminal CT15. The sixteenth terminal AT16 may be connected to the sixteenth terminal CT16. The seventeenth terminal AT17 may be connected to the seventeenth terminal CT17.

In one or more embodiments, each of the terminals included in the intermediate connector APCB-CT may have the same (or substantially the same) shape as the first probe PRB1 of FIG. 10. For example, each of the terminals included in the intermediate connector APCB-CT may include a body portion and an insertion portion. The insertion portion of each of the terminals included in the intermediate connector APCB-CT may be received in the insertion groove CT-OP of FIG. 10.

As illustrated in FIG. 17, the auxiliary connector CNT″ may include terminals. For example, the auxiliary connector CNT″ may include a first terminal CT1′, a second terminal CT2′, a third terminal CT3′, a fourth terminal CT4′, a fifth terminal CT5′, a sixth terminal CT6′, a seventh terminal CT7′, an eighth terminal CT8′, a ninth terminal CT9′, a tenth terminal CT10′, an eleventh terminal CT11′, a twelfth terminal CT12′, a thirteenth terminal CT13′, a fourteenth terminal CT14′, a fifteenth terminal CT15′, a sixteenth terminal CT16′, and a seventeenth terminal CT17′. The auxiliary connector CNT″ may refer to a set of the terminals. The first terminal CT1′, the second terminal CT2′, the third terminal CT3′, the fourth terminal CT4′, the fifth terminal CT5′, the sixth terminal CT6′, the seventh terminal CT7′, the eighth terminal CT8′, the ninth terminal CT9′, the tenth terminal CT10′, the eleventh terminal CT11′, the twelfth terminal CT12′, the thirteenth terminal CT13′, the fourteenth terminal CT14′, the fifteenth terminal CT15′, the sixteenth terminal CT16′, and the seventeenth terminal CT17′ may be spaced apart from each other in a plan view. Each of the terminals included in the auxiliary connector CNT″ may protrude from the auxiliary circuit board APCB in the third direction DR3. The terminals included in the auxiliary connector CNT″ may be repeatedly arranged along the second direction DR2.

The auxiliary connector CNT″ may be electrically connected to the intermediate connector APCB-CT. For example, each of the terminals included in the auxiliary connector CNT″ may be electrically connected to a corresponding terminal of the terminals included in the intermediate connector APCB-CT. The first terminal CT1′ may be electrically connected to the first terminal AT1 through a first auxiliary wire N1. The second terminal CT2′ may be electrically connected to the second terminal AT2 through a second auxiliary wire N2. The third terminal CT3′ may be electrically connected to the third terminal AT3 through a third auxiliary wire N3. The fourth terminal CT4′ may be electrically connected to the fourth terminal AT4 through a fourth auxiliary wire N4. The fifth terminal CT5′ may be electrically connected to the fifth terminal AT5 through a fifth auxiliary wire N5. The sixth terminal CT6′ may be electrically connected to the sixth terminal AT6 through a sixth auxiliary wire N6. The seventh terminal CT7′ may be electrically connected to the seventh terminal AT7 through a seventh auxiliary wire N7. The eighth terminal CT8′ may be electrically connected to the eighth terminal AT8 through an eighth auxiliary wire N8. The ninth terminal CT9′ may be electrically connected to the ninth terminal AT9 through a ninth auxiliary wire N9. The tenth terminal CT10′ may be electrically connected to the tenth terminal AT10 through a tenth auxiliary wire N10. The eleventh terminal CT11′ may be electrically connected to the eleventh terminal AT11 through an eleventh auxiliary wire N11. The twelfth terminal CT12′ may be electrically connected to the twelfth terminal AT12 through a twelfth auxiliary wire N12. The thirteenth terminal CT13′ may be electrically connected to the thirteenth terminal AT13 through a thirteenth auxiliary wire N13. The fourteenth terminal CT14′ may be electrically connected to the fourteenth terminal AT14 through a fourteenth auxiliary wire N14. The fifteenth terminal CT15′ may be electrically connected to the fifteenth terminal AT15 through a fifteenth auxiliary wire N15. The sixteenth terminal CT16′ may be electrically connected to the sixteenth terminal AT16 through a sixteenth auxiliary wire N16. The seventeenth terminal CT17′ may be electrically connected to the seventeenth terminal AT17 through a seventeenth auxiliary wire N17.

The auxiliary connector CNT″ may be electrically connected to the circuit board bonding portions PCB-B through auxiliary wires, the intermediate connector APCB-CT, the connector CNT, and the wires. For example, the first terminal CT1′ may be electrically connected to the first circuit board bonding portion PB1 through the first auxiliary wire N1, the first terminal AT1, the first terminal CT1, and the first wire L1. The second terminal CT2′ may be electrically connected to the second circuit board bonding portion PB2 through the second auxiliary wire N2, the second terminal AT2, the second terminal CT2, and the second wire L2. The third terminal CT3′ may be electrically connected to the third circuit board bonding portion PB3 through the third auxiliary wire N3, the third terminal AT3, the third terminal CT3, and the third wire L3. The fourth terminal CT4′ may be electrically connected to the fourth circuit board bonding portion PB4 through the fourth auxiliary wire N4, the fourth terminal AT4, the fourth terminal CT4, and the fourth wire L4. The fifth terminal CT5′ may be electrically connected to the fifth circuit board bonding portion PB5 through the fifth auxiliary wire N5, the fifth terminal AT5, the fifth terminal CT5, and the fifth wire L5. The sixth terminal CT6′ may be electrically connected to the sixth circuit board bonding portion PB6 through the sixth auxiliary wire N6, the sixth terminal AT6, the sixth terminal CT6, and the sixth wire L6. The seventh terminal CT7′ may be electrically connected to the seventh circuit board bonding portion PB7 through the seventh auxiliary wire N7, the seventh terminal AT7, the seventh terminal CT7, and the seventh wire L7. The eighth terminal CT8′ may be electrically connected to the eighth circuit board bonding portion PB8 through the eighth auxiliary wire N8, the eighth terminal AT8, the eighth terminal CT8, and the eighth wire L8. The ninth terminal CT9′ may be electrically connected to the ninth circuit board bonding portion PB9 through the ninth auxiliary wire N9, the ninth terminal AT9, the ninth terminal CT9, and the ninth wire L9. The tenth terminal CT10′ may be electrically connected to the tenth circuit board bonding portion PB10 through the tenth auxiliary wire N10, the tenth terminal AT10, the tenth terminal CT10, and the tenth wire L10. The eleventh terminal CT11′ may be electrically connected to the eleventh circuit board bonding portion PB11 through the eleventh auxiliary wire N11, the eleventh terminal AT11, the eleventh terminal CT11, and the eleventh wire L11. The twelfth terminal CT12′ may be electrically connected to the twelfth circuit board bonding portion PB12 through the twelfth auxiliary wire N12, the twelfth terminal AT12, the twelfth terminal CT12, and the twelfth wire L12. The thirteenth terminal CT13′ may be electrically connected to the thirteenth circuit board bonding portion PB13 through the thirteenth auxiliary wire N13, the thirteenth terminal AT13, the thirteenth terminal CT13, and the thirteenth wire L13. The fourteenth terminal CT14′ may be electrically connected to the fourteenth circuit board bonding portion PB14 through the fourteenth auxiliary wire N14, the fourteenth terminal AT14, the fourteenth terminal CT14, and the fourteenth wire L14. The fifteenth terminal CT15′ may be electrically connected to the fifteenth circuit board bonding portion PB15 through the fifteenth auxiliary wire N15, the fifteenth terminal AT15, the fifteenth terminal CT15, and the fifteenth wire L15. The sixteenth terminal CT16′ may be electrically connected to the sixteenth circuit board bonding portion PB16 through the sixteenth auxiliary wire N16, the sixteenth terminal AT16, the sixteenth terminal CT16, and the sixteenth wire L16. The seventeenth terminal CT17′ may be electrically connected to the seventeenth circuit board bonding portion PB17 through the seventeenth auxiliary wire N17, the seventeenth terminal AT17, the seventeenth terminal CT17, and the seventeenth wire L17.

In one or more embodiments, each of the first terminal CT1′, the second terminal CT2′, the third terminal CT3′, the fourth terminal CT4′, the fifth terminal CT5′, the sixth terminal CT6′, the seventh terminal CT7′, the eighth terminal CT8′, the ninth terminal CT9′, the tenth terminal CT10′, the eleventh terminal CT11′, the twelfth terminal CT12′, the thirteenth terminal CT13′, the fourteenth terminal CT14′, the fifteenth terminal CT15′, the sixteenth terminal CT16′, and the seventeenth terminal CT17′ may have the same (or substantially the same) shape as the first terminal CT1 of FIG. 10. For example, each of the first terminal CT1′, the second terminal CT2′, the third terminal CT3′, the fourth terminal CT4′, the fifth terminal CT5′, the sixth terminal CT6′, the seventh terminal CT7′, the eighth terminal CT8′, the ninth terminal CT9′, the tenth terminal CT10′, the eleventh terminal CT11′, the twelfth terminal CT12′, the thirteenth terminal CT13′, the fourteenth terminal CT14′, the fifteenth terminal CT15′, the sixteenth terminal CT16′, and the seventeenth terminal CT17′ may include a body portion, and the body portion may include (or define) an insertion groove.

Each of the probes (e.g., the probes PRBS of FIG. 9) may be connected to a portion of the auxiliary connector CNT″. For example, each of the probes may be connected to a corresponding terminal of the terminals included in the auxiliary connector CNT″. Using the probes, the measuring of the resistance of at least some of the driving chip bonding portions IC-B and the measuring of the resistance of at least some of the circuit board bonding portions PCB-B, as described above with reference to FIGS. 5, 8, and 9, may be performed.

After the measuring of the resistance of at least some of the driving chip bonding portions IC-B and the measuring of the resistance of at least some of the circuit board bonding portions PCB-B, the probes may be removed from the auxiliary connector CNT″. After the probes are removed from the auxiliary connector CNT″, the electronic module (e.g., the electronic module EM of FIG. 2) may be connected to the auxiliary connector CNT″. The electronic module may be electrically connected to the circuit board PCB through the auxiliary connector CNT″ and the auxiliary circuit board APCB.

Aspects of some embodiments of the present disclosure can be applied to various display devices. For example, aspects of some embodiments of the present disclosure may be applicable to various display devices such as display devices for vehicles, ships and aircraft, portable communication devices, display devices for exhibition or information transmission, medical display devices, and the like.

The foregoing is illustrative of aspects of some embodiments and is not to be construed as limiting thereof. Although aspects of some embodiments have been described, those skilled in the art will readily appreciate that many modifications are possible in the embodiments without materially departing from the novel teachings and characteristics of embodiments according to the present disclosure. Accordingly, all such modifications are intended to be included within the scope of embodiments according to the present disclosure as defined in the appended claims, and their equivalents. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, and their equivalents.

What is claimed is:

1. A display unit comprising:
a display panel including a display area in which pixels are located and a non-display area surrounding at least a portion of the display area;
a driving chip attached to the display panel by driving chip bonding portions;
a circuit board attached to the display panel by circuit board bonding portions, wherein the circuit board bonding portions include a first circuit board bonding portion electrically separated from the driving chip; and
a connector at one side of the circuit board and electrically connected to the first circuit board bonding portion.

2. The display unit of claim 1, wherein the first circuit board bonding portion and the display area are electrically separated from each other.

3. The display unit of claim 1, wherein the first circuit board bonding portion is at an outermost portion of the circuit board bonding portions.

4. The display unit of claim 1, wherein the circuit board bonding portions further include,
a second circuit board bonding portion electrically separated from each of the driving chip and the display area, electrically connected to the connector, and adjacent to the first circuit board bonding portion;
a third circuit board bonding unit electrically separated from each of the driving chip and the display area, electrically connected to the connector, and adjacent to the second circuit board bonding portion; and
a fourth circuit board bonding portion electrically separated from each of the driving chip and the display area, electrically connected to the connector, and adjacent to the third circuit board bonding portion.

5. The display unit of claim 1, wherein the connector includes a terminal including an insertion groove, and the first circuit board bonding portion and the terminal are connected through wiring.

6. The display unit of claim 1, wherein the driving chip bonding portions include a first driving chip bonding portion electrically separated from the display area and electrically connected to the connector.

7. The display unit of claim 6, wherein the first driving chip bonding portion is electrically connected to the connector through one of the circuit board bonding portions.

8. The display unit of claim 6, wherein the first driving chip bonding portion is at an outermost portion of the driving chip bonding portions.

9. The display unit of claim 1, further comprising:
an auxiliary circuit board attached to one side of the circuit board through an intermediate connector electrically connected to the connector.

10. The display unit of claim 9, further comprising:
an auxiliary connector located on one side of the auxiliary circuit board and electrically connected to the first circuit board bonding portion.

11. The display unit of claim 10, wherein the auxiliary connector is electrically connected to the circuit board bonding portions through the intermediate connector and the connector.

12. The display unit of claim 11, wherein the auxiliary connector includes a terminal including an insertion groove,
the intermediate connector includes a terminal electrically connected to the terminal of the auxiliary connector through an auxiliary wiring, and
the terminal of the auxiliary connector is electrically connected to the first circuit board bonding portion through the auxiliary wiring, the terminal of the intermediate connector, the terminal of the connector, and a wiring.

13. An electronic device comprising:
a display unit; and
an electronic module configured to control an operation of the display unit, wherein
the display unit includes:
a display panel including a display area in which pixels are located and a non-display area surrounding at least a portion of the display area;
a driving chip attached to the display panel by driving chip bonding portions;
a circuit board attached to the display panel by circuit board bonding portions, wherein the circuit board bonding portions include a first circuit board bonding portion electrically separated from the driving chip; and
a connector on one side of the circuit board and electrically connected to the first circuit board bonding portion.

14. A method of measuring resistance of an electronic device, the method comprising:
connecting a first probe to a portion of a connector electrically connected to a first circuit board bonding portion attaching a display panel and a circuit board;
connecting a second probe to a portion of the connector electrically connected to a second circuit board bonding portion attaching the display panel and the circuit board, wherein the second circuit board bonding portion is spaced apart from the first circuit board bonding portion in a plan view;
connecting a third probe to a portion of the connector electrically connected to a third circuit board bonding portion attaching the display panel and the circuit board, wherein the third circuit board bonding portion is spaced apart from the first circuit board bonding portion and the second circuit board bonding portion in the plan view; and
connecting a fourth probe to a portion of the connector electrically connected to a fourth circuit board bonding portion attaching the display panel and the circuit board, wherein the fourth circuit board bonding portion is spaced apart from the first circuit board bonding portion, the second circuit board bonding portion, and the third circuit board bonding portion in the plan view.

15. The method of claim 14, wherein the connecting of the first probe to the portion of the connector includes connecting the first probe to a first terminal included in the connector, and
the connecting of the second probe to the portion of the connector includes connecting the second probe to a second terminal included in the connector and spaced apart from the first terminal of the connector in the plan view.

16. The method of claim 15, wherein the connecting of the third probe to the portion of the connector includes connecting the third probe to a third terminal included in the connector and spaced apart from each of the first terminal of the connector and the second terminal of the connector in the plan view, and
the connecting of the fourth probe to the portion of the connector includes connecting the fourth probe to a fourth terminal included in the connector and spaced apart from each of the first terminal of the connector, the second terminal of the connector, and the third terminal of the connector in the plan view.

17. The method of claim 14, further comprising:
connecting a fifth probe to a portion of the connector electrically connected to a first driving chip bonding portion attaching the display panel and the driving chip;
connecting a sixth probe to a portion of the connector electrically connected to a second driving chip bonding portion attaching the display panel and the driving chip and spaced apart from the first driving chip bonding portion;
connecting a seventh probe to a portion of the connector electrically connected to a third driving chip bonding portion attaching the display panel and the driving chip and spaced apart from each of the first driving chip bonding portion and the second driving chip bonding portion; and
connecting an eighth probe to a portion of the connector electrically connected to a fourth driving chip bonding portion attaching the display panel and the driving chip and spaced apart from each of the first driving chip bonding portion, the second driving chip bonding portion, and the third driving chip bonding portion.

18. The method of claim 17, wherein the connecting of the fifth probe to the portion of the connector includes connecting the fifth probe to a fifth terminal included in the connector, and
the connecting of the sixth probe to the portion of the connector includes connecting the sixth probe to a sixth terminal included in the connector and spaced apart from the fifth terminal in the plan view.

19. The method of claim 18, wherein the connecting of the seventh probe to the portion of the connector includes connecting the seventh probe to a seventh terminal included in the connector and spaced apart from each of the fifth terminal of the connector and the sixth terminal of the connector in the plan view, and
the connecting of the eighth probe to the portion of the connector includes connecting the eighth probe to an eighth terminal included in the connector and spaced apart from each of the fifth terminal of the connector, the sixth terminal of the connector, and the seventh terminal of the connector in the plan view.

20. The method of claim 14, wherein a current is configured to be applied to the first circuit board bonding portion through the first probe,
a current is configured to be applied to the second circuit board bonding portion through the second probe,
a voltage is configured to be applied to the third circuit board bonding portion through the third probe, and
a voltage is configured to be applied to the fourth circuit board bonding portion through the fourth probe.
